(19) United States
(12) Patent Application Publication
(10) Pub. No.: US 2026/0099644 A1
(43) Pub. Date: Apr. 9, 2026

(54) SYSTEMS AND METHODS FOR EVALUATING DEVICES EXHIBITING NEAR-ZERO SCATTERING UTILIZING NEGATIVE INDEX METAMATERIALS AND/OR NEGATIVE KERR COEFFICIENT MATERIALS

(71) Applicant: The Penn State Research Foundation, University Park, PA (US)

(72) Inventor: Taoufik Meklachi, Middletown, PA (US)

(73) Assignee: The Penn State Research Foundation, University Park, PA (US)

(21) Appl. No.: 19/350,967

(22) Filed: Oct. 6, 2025

Related U.S. Application Data
(60) Provisional application No. 63/704,272, filed on Oct. 7, 2024.
(60) Provisional application No. 63/779,458, filed on Mar. 28, 2025.

(51) Int. Cl. G06F 30/20

(52) U.S. Cl. CPC G06F 30/20

(57) ABSTRACT

Embodiments can relate to systems and methods for developing a structure exhibiting near-zero wave scattering. The technique can involve receiving a number (n) of layers for the structure, each layer comprising a material, receiving a susceptibility coefficient (η) for one or more layers, receiving a wave number (k) for an optical wave or acoustic wave that will be propagated through one or more layers, receiving an electric field measurement (u) to be applied to one or more layers, receiving a refractive index coefficient (η^{k}) for one or more layers; and/or receiving a Kerr coefficient (β) for one or more layers. The technique can involve solving near-zero wave scattering equation to optimize parameters related to one or more materials for the structure and/or parameters related to geometric dimensions for the structure.

### CROSS-REFERENCE TO RELATED APPLICATIONS

This patent application is related to and claims the benefit of priority of U.S. provisional patent application No. 63/704,272, filed on Oct. 7, 2024, and U.S. provisional application No. 63/779,458, filed on Mar. 28, 2025, the entire contents of each being incorporated herein by reference.

### FIELD OF THE INVENTION

Embodiments can relate to systems and methods for developing and evaluating devices exhibiting near-zero scattering utilizing negative index metamaterials and/or negative Kerr coefficient materials.

### BACKGROUND OF THE INVENTION

Known techniques are available for deriving an effective refractive index formula for complex multilayered structures. However, existing techniques are deficient when multilayered structures comprise high-contrast media with nonlinear responses. In particular, existing techniques are unable to effectively consider the interplay between material properties, geometry, and the strength of the nonlinearity.

### SUMMARY OF THE INVENTION

An exemplary embodiment can relate to a system for developing a structure exhibiting near-zero wave scattering. The system can include a processor in operative association with a memory, the memory having instructions stored thereon that when executed by the processor can cause the processor to: receive a number (η) of layers for the structure, each layer comprising a material; receive a susceptibility coefficient (i) for one or more layers; receive a wave number (k) for an optical wave or acoustic wave that will be propagated through one or more layers; receive an electric field measurement (u) to be applied to one or more layers; receive a refractive index coefficient (η^{k}) for one or more layers; and/or receive a Kerr coefficient (β) for one or more layers. The instructions stored thereon can cause the processor to solve one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

η₀ is a susceptibility coefficient for a homogeneous layer with constant susceptibility. β₀ is a Kerr coefficient for a homogenous layer within a constant electric field. η_{eff} is an effective susceptibility coefficient for the structure, wherein η_{eff} captures a combined contribution of each η for each layer of the structure. λ is resonance of a layer.

The instructions stored thereon can cause the processor to generate an output based on solving the one or more equations, the output including:
η for one or more layers;
a range of k values for the structure;
a range of u for one or more layers;
η^{k} for one or more layers;
β for one or more layers;
β_{eff} for the structure;
λ for one or more layers; and/or
Δλ for the structure.

The output can include identification of one or more materials for one or more layers.

The output can include identification of one or more geometric dimensions for one or more layers.

The identification of one or more materials for one or more layers can include identification of an electrical property, a magnetic property, an optical property, a mechanical property, and/or a chemical property.

The output can include optimized parameters related to one or more materials for the structure and optimized parameters related to geometric dimensions for the structure. The structure can be a component of a nonlinear optical device or a component of a nonlinear acoustic device.

An exemplary embodiment can relate to a system for evaluating a structure for a nonlinear optical component or a nonlinear acoustic component. The structure can comprise plural layers of material. The system can include a processor in operative association with a memory, the memory having instructions stored thereon that when executed by the processor can cause the processor to: receive a parameter related to one or more materials for the structure; receive a geometric dimension related to one or more layers of the structure; generate an output that is a determination that, or a prediction of whether, the structure will exhibit near-zero wave scattering, the determination or prediction based on solving one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

n=the number of layers of the structure. η=susceptibility coefficient for a layer. k=a wave number for an optical wave or acoustic wave that will be propagated through the structure. u=an electric field measurement to be applied to the structure. η^{k}=a refractive index coefficient for a layer. β=a Kerr coefficient for a layer. β is a susceptibility coefficient for a homogeneous layer with constant susceptibility. β₀ is a Kerr coefficient for a homogenous layer within a constant electric field. η_{eff} is an effective susceptibility coefficient for the structure, wherein η_{eff} captures a combined contribution of each η for each layer of the structure. λ is resonance of a layer.

The output can include a determination or a prediction of a resonance shift Δλ for the structure.

The output can include a determination or a prediction of:
η for one or more layers;
a range of k values for the structure;
a range of u for one or more layers;
η^{k} for one or more layers;
β for one or more layers;
η_{eff} for the structure; and/or
λ for one or more layers.

An exemplary embodiment can relate to a method for developing a structure exhibiting near-zero wave scattering. The method can involve: receiving a number (n) of layers for the structure, each layer comprising a material; receiving a susceptibility coefficient (η) for one or more layers; receiving a wave number (k) for an optical wave or acoustic wave that will be propagated through one or more layers; receiving an electric field measurement (u) to be applied to one or more layers; receiving a refractive index coefficient (η^{k}) for one or more layers; and/or receiving a Kerr coefficient (β) for one or more layers. The methos can involve solving one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

η₀ is a susceptibility coefficient for a homogeneous layer with constant susceptibility. β₀ is a Kerr coefficient for a homogenous layer within a constant electric field. η_{eff} is an effective susceptibility coefficient for the structure, wherein η_{eff} captures a combined contribution of each η for each layer of the structure. λ is resonance of a layer;

The method can involve determining or predicting based on solving the one or more equations:
η for one or more layers;
a range of k values for the structure;
a range of u for one or more layers;
η^{k} for one or more layers;
β for one or more layers;
η_{eff} for the structure;
λ for one or more layers; and/or
Δλ for the structure.

The method can involve determining or predicting, based on solving the one or more equations, one or more materials for one or more layers. The method can involve determining or predicting, based on solving the one or more equations, one or more geometric dimensions for one or more layers.

The method can involve determining or predicting, based on solving the one or more equations, an electrical property, a magnetic property, an optical property, a mechanical property, and/or a chemical property.

The method can involve optimizing, based on solving the one or more equations, parameters related to one or more materials for the structure. The method can involve optimizing, based on solving the one or more equations, parameters related to geometric dimensions for the structure. The structure can be a component of a nonlinear optical device or a component of a nonlinear acoustic device.

An exemplary embodiment can relate to a method for evaluating a structure for a nonlinear optical component or a nonlinear acoustic component, the structure comprising plural layers of material. The method can involve receiving a parameter related to one or more materials for the structure. The method can involve receiving a geometric dimension related to one or more layers of the structure. The method can involve determining or predicting that the structure will exhibit near-zero wave scattering, the determination or prediction based on solving one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

n=the number of layers of the structure. η=susceptibility coefficient for a layer. k=a wave number for an optical wave or acoustic wave that will be propagated through the structure. u=an electric field measurement to be applied to the structure. η^{k}=a refractive index coefficient for a layer. β=a Kerr coefficient for a layer. η₀ is a susceptibility coefficient for a homogeneous layer with constant susceptibility. β₀ is a Kerr coefficient for a homogenous layer within a constant electric field. η_{eff} is an effective susceptibility coefficient for the structure, wherein η_{eff} captures a combined contribution of each η for each layer of the structure. λ is resonance of a layer.

The method can involve determining or predicting, based on solving the one or more equations, a resonance shift Δλ for the structure.

The method can involve determining or predicting, based on solving the one or more equations:
η for one or more layers;
a range of k values for the structure;
a range of u for one or more layers;
η^{k} for one or more layers;
β for one or more layers;
η_{eff} for the structure; and/or
λ for one or more layers.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 shows an exemplary system or developing and evaluating devices exhibiting near-zero scattering.

FIGS. 2-4 show schematics of exemplary structures.

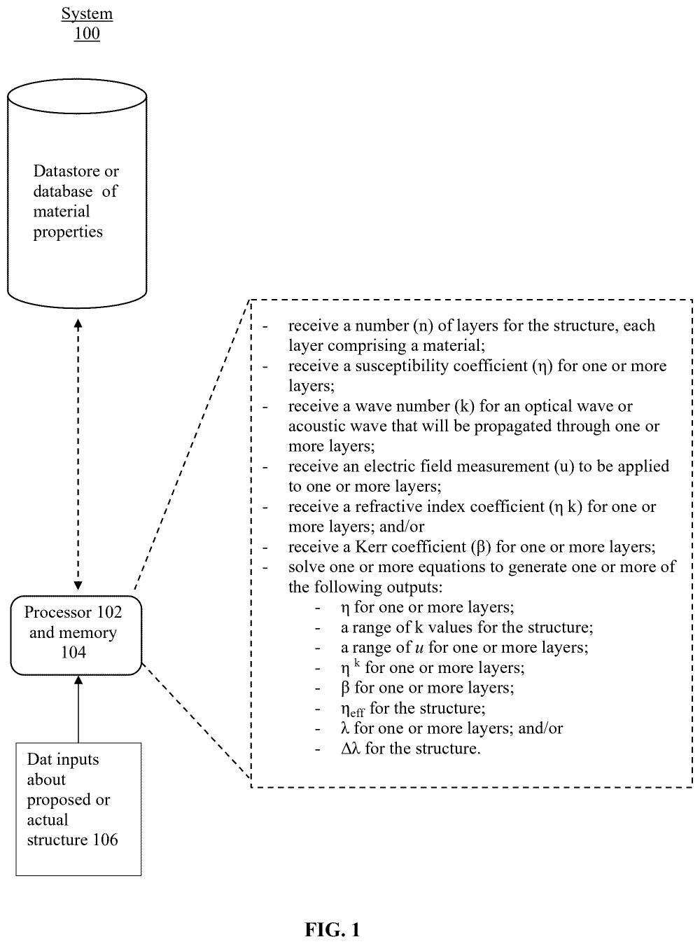

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

An exemplary embodiment can relate to a system 100 for developing a structure 106 exhibiting near-zero wave scattering. The system 100 can include a processor 102 in operative association with a memory 104. The memory 104 can having instructions stored thereon that when executed by the processor 102 can cause the processor 102 to execute any of the functions disclosed herein.

Any of the processors 102 can include or be operatively associated with a memory 104. The memory 104 can store instructions thereon which can be executed by the processor 102 to perform any of the functions disclosed herein. The instructions can be in the form of computer logic, algorithms, models, etc. and stored as a computer program, a data structure, etc. While exemplary embodiments may be described and/or illustrated with one processor 102 and one memory 104, it is understood that any of the components can include any number of processors 102 and memories 104 within the single processor 102 or memory 104.

The processor 102 can be part of or in communication with a machine (logic, one or more components, circuits (e.g., modules), or mechanisms). The processor 102 can be hardware (e.g., processor, integrated circuit, central processing unit, microprocessor, core processor, computer device, etc.), firmware, software, or any combination thereof configured to perform operations by execution of instructions embodied in algorithms, data processing program logic, artificial intelligence programming, automated reasoning programming, etc. Use of processors 102 herein can include any one or combination of a Graphics Processing Unit (GPU), a Field Programmable Gate Array (FPGA), a Central Processing Unit (CPU), and so forth. The processor 102 can include one or more operating modules. An operating module can be a software or firmware operating module configured to implement any of the method steps disclosed herein. The operating module can be embodied as software and stored in memory 104, the memory 104 being operatively associated with the processor 102. An operating module can be embodied as a web application, a desktop application, a console application, and so forth.

The processor 102 can include or be associated with a computer or machine-readable medium. The computer or machine-readable medium can include memory. The computer or machine-readable medium can be configured to store one or more instructions thereon. The instructions can be in the form of algorithms, program logic, a model, or any combination therefor that cause the processor 102 to perform any of the functions described herein.

Any of the memory 104 discussed herein can be computer readable memory configured to store data. The memory 104 can include a volatile or non-volatile, transitory or non-transitory memory, and be embodied as an in-memory, an active memory, a cloud memory, or any combination thereof. Embodiments of the memory 104 can include an operating module and other circuitry to allow for the transfer of data to and from the memory 104, which can include to and from other components of a communication system. This transfer can be via hardwire or wireless transmission. The communication system can include transceivers, which can be used in combination with switches, receivers, transmitters, routers, gateways, waveguides, etc. to facilitate communications via a communication approach or protocol for controlled and coordinated signal transmission and processing to any other component or combination of components of the communication system. The transmission can be via a communication link. The communication link can be electronic-based, optical-based, opto-electronic-based, quantum-based, phononic-based, etc.

The processor 102 can be in communication with other processors of other devices (e.g., a computer device, a desktop computer, a laptop computer, a computer system, etc.). Any of those other devices can include any of the exemplary processors 102 disclosed herein. Any of the processors 102 can have transceivers or other communication devices/circuitry to facilitate transmission and reception of wireless signals. Any of the processors 102 can include an Application Programming Interface (API) as a software intermediary that allows two applications to talk to each other. Use of an API can allow software of the processor 102 of the system to communicate with software of the processor of the other device(s), if the processor 102 of the system is not the same processor 102 of the device.

Any data transmission between a processor 102 and a memory 104, between a processor 102 and a database, between a processor 102 and processors 102 of other devices, between a processor 102 of one operating module and a processor 102 of another operating module, etc. can be via a pull operation (e.g., the processor 102 can pull the data) or a push operation (e.g., the data can be pushed to the processor 102). The processor 102 can receive and process the data in steaming format, store it in memory before being processed, etc.

The processor 102 can be configured to be a component of, used in combination with, or in communication with another device/system—e.g., this can include the processor being part of the device/system, the device/system being part of the processor, the processor in communication with the device/system, etc. “Being part of” can include being on a same substrate or integrated circuit.

A processor 102 can be a component of, used in combination with, or in communication with a predictive modeling system, a decision support system, an automated control system, etc. A processor 102 can use the techniques disclosed herein to assist with or augment the performance of these devices/systems.

The system 100 can be used to obtain information about a desired structure 106 configuration (e.g., number of layers, type of material, material properties (e.g., electrical, chemical, optical, magnetic, etc.) of each material, thickness of each layer, etc.) and determine or predict how the structure will behave when optical or acoustic waves are propagated through the structure 106. The structure 106 may be a component that is contemplated for use within an optical device, an acoustic device, etc. For instance, the structure 106 can be a waveguide an antenna, a lens, a coating, etc. for an optical cloaking device, an acoustic metamaterial sensor, an imaging contrast component, etc. It is contemplated for the structure 106 to be a component of a nonlinear optical device or a component of a nonlinear acoustic device. The determination or prediction can include whether the structure 106 will exhibit scattering, the degree of scattering, will exhibit near-zero scattering, will have a desired effective optical refractive index, will have a desired effective acoustic refractive index, will have a desired effective Kerr coefficient, etc. The determination or prediction can be for one or more layers 108 of the structure 106 or for the structure 106 itself. The determinations and predictions can be performed by the processor 102 via execution of one or more algorithms stored on the memory 104. The one or more algorithms can embody one or more of the formulas disclosed herein. As will be explained, the formulas allow for more accurate determinations or predictions as well as provide a means to more efficiently obtain the determination or prediction because utilizing the formulas can obviate the need for computationally intensive numerical methods/simulations.

In addition to, or in the alternative to, determining or predicting how a proposed structure 106 will behave, the system 100 can evaluate an existing structure 106. Thus, instead of entering proposed specifications about a proposed structure 106, a user can enter actual specifications of an existing structure 106, wherein the system 100 can generate an output that is a determination about whether the structure 106 exhibits scattering, the degree of scattering, whether the structure 106 exhibits near-zero scattering, what the effective optical refractive index is, what the effective acoustic refractive index is, etc. As can be appreciated, the system 100 can provide a means to perform non-destructive evaluations on structures 106.

As noted above, the instructions can cause the processor 102 to execute any of the functions disclosed herein. These functions can include receiving data inputs and generating data outputs. Receipt of data inputs can be via a user interface displayed on a display screen of a computer device. For instance, a user can enter data inputs via the user interface. In addition, or in the alternative, the processor 102 can retrieve data inputs from a datastore, database, a measurement apparatus, etc. The data outputs can be generated via the user interface and displayed on the display of the computer device.

The instructions can cause the processor 102 to receive a number (n) of layers 108 for the structure 106. Each layer 108 can comprise a material, for example. n can be the number of desired layers 108 of a proposed structure 106, a range of acceptable layers 108 for a proposed structure 106, the number of actual layers 108 of an actual structure 106 in an optical or acoustic system, etc. The instructions can cause the processor 102 to receive a susceptibility coefficient (η) for one or more layers 108. η can be a desired η for a proposed layer 108, an acceptable range of η for a proposed layer 108, a η for an actual layer 108 of a structure 106 in an optical or acoustic system, etc. The instructions can cause the processor 102 to receive a wave number (k) for an optical wave or acoustic wave that will be propagated through one or more layers 108. k can be a desired k for a proposed layer 108, an acceptable range of k for a proposed layer 108, a k for an actual layer 108 of a structure 106 in an optical or acoustic system, etc. The instructions can cause the processor 102 to receive an electric field measurement (u) to be applied to one or more layers 108. u can be a desired u for a proposed layer 108, an acceptable range of u for a proposed layer 108, a u for an actual layer 108 of a structure 106 in an optical or acoustic system, etc. The instructions can cause the processor 102 to receive a refractive index coefficient (η^{k}) for one or more layers 108. η^{k} can be a desired η^{k} for a proposed layer 108, an acceptable range of η^{k} for a proposed layer 108, a η^{k} for an actual layer 108 of a structure 106 in an optical or acoustic system, etc. The instructions can cause the processor 102 to receive a Kerr coefficient (β) for one or more layers 108. β can be a desired β for a proposed layer 108, an acceptable range of β for a proposed layer 108, a β for an actual layer 108 of a structure 106 in an optical or acoustic system, etc.

The instructions can cause the processor 102 to solve one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

η₀ is a susceptibility coefficient for a homogeneous layer with constant susceptibility. β₀ is a Kerr coefficient for a homogenous layer within a constant electric field. η_{eff} is an effective susceptibility coefficient for the structure, wherein η_{eff} captures a combined contribution of each η for each layer of the structure. λ is resonance of a layer.

As will be explained herein, use of these formulas can allow the system 100 to determine or predict material characteristics of the structure 106 without having to execute computationally intensive numerical methods/simulations. This results in increased speed, increased accuracy, reduced computational resources needed to achieve the same or better result, etc. for the system. In some instances, it provides a determination or prediction when it otherwise could not be provided—i.e., use of the formulas can generate a result whereas existing numerical methods/simulations could not. The EXAMPLES section of this disclosure demonstrates how these formulas can be solved to generate outputs representative of material characteristics of the structure 106.

The instructions can cause the processor 102 to generate an output based on solving the one or more equations. The output can include:
η for one or more layers;
a range of k values for the structure;
a range of u for one or more layers;
η^{k} for one or more layers;
β for one or more layers;
η_{eff} for the structure;
λ for one or more layers; and/or
Δλ for the structure.

A user can then use these outputs to identify which material(s) to use for the layer(s) 108, which geometric dimensions to use for the layer(s) 108, which electrical, magnetic, optical, mechanical, and/or a chemical properties would be suitable for a material, etc. This can be done by referencing publications (e.g., NIST-JANAF tables) about material properties to select materials for the layer(s) 108. Thus, a user can select the materials and the geometries of the layer(s) 108 when designing a proposed structure 106. Alternatively, a user can use these outputs to understand how an existing structure 106 would perform in an optical or acoustic system.

In addition, or in the alternative, the processor 102 can have access to the material property data (e.g., can access a database of material property data) and automatically select or down-select materials, geometries, number of layers 108, etc. to use for a proposed structure 106. Thus, the output can include identification of one or more materials for one or more layers 108. The output can also include identification of one or more geometric dimensions for one or more layers 108. The identification of one or more materials for one or more layers 108 can also include identification of an electrical property, a magnetic property, an optical property, a mechanical property, a chemical property, etc. The processor 102 can perform this via use of a model (e.g., multivariate analysis, regression analysis, use of an objective or cost function, etc.).

The output can include optimized parameters related to one or more materials for the structure 106 and optimized parameters related to geometric dimensions for the structure 106. Again, the optimization can be performed via a multivariate analysis model, a regression analysis model, an objective or cost function model, etc.

As noted above, the system 100 can be used to assist with development of a proposed structure 106, but the system 100 can also be used to evaluate an existing structure 106. Thus, the system 100 can be configured for evaluating a structure 106 for a nonlinear optical component or a nonlinear acoustic component. The structure 106 can comprise plural layers of material. The system 100 can include a processor 102 in operative association with a memory 104. The memory 104 can have instructions stored thereon that when executed by the processor 102 can cause the processor 102 to receive a parameter related to one or more materials for the structure 106. The instructions can cause the processor 102 to receive a geometric dimension related to one or more layers 108 of the structure. The instructions can cause the processor 102 to generate an output that is a determination that, or a prediction of whether, the structure 106 will exhibit near-zero wave scattering. The determination or prediction can be based on solving one or more of the following equations:

$${\sum }_{k = 1}^{n} {η}_{0}^{k} {U}_{k} + {β}_{0}^{k} {U}_{k}^{β} = 0 ;$$

$${\sum }_{k = 1}^{n} {η}_{0}^{k} {U}_{k} = 0 ;$$

$${η}_{in}^{0} {U}_{in} + {η}_{out}^{0} {U}_{out} + {β}_{in}^{0} {U}_{in β} + {β}_{out}^{0} {U}_{out β} = 0 ;$$

$${η}_{eff} \approx \frac{η {U}_{0} + β {U}_{1}}{{U}_{0}} ;$$

$${η}_{eff} = \frac{{\sum }_{k = 1}^{n} {η}^{k} {U}_{k} + {β}^{k} {U}_{k}^{β}}{{U}_{0}} ;$$

$${η}_{eff} = \frac{{\sum }_{k = 1}^{n} {η}^{k} {U}_{k}}{{U}_{0}} ;$$

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) .$$

The output can include a determination or a prediction of:
η for one or more layers;
a range of k values for the structure;
a range of u for one or more layers;
η^{k} for one or more layers;
β for one or more layers;
η_{eff} for the structure;
λ for one or more layers; and/or
a resonance shift Δλ for the structure.

### EXAMPLES

The following examples include exemplary implementations and test results of embodiments disclosed herein.

### Example 1

The pursuit of near-zero scattering in high-contrast media has garnered significant attention due to its potential to revolutionize various fields, from enhancing stealth capabilities to enabling novel optical and acoustic devices. While achieving minimal scattering in linear media has been a subject of extensive research, extending these concepts to nonlinear media presents unique challenges and opportunities. EXAMPLE 1 demonstrates how techniques disclosed herein can not only achieve near-zero scattering in both linear and nonlinear high-contrast small media but also to derive an effective refractive index formula for such complex configurations. The ability to manipulate the scattering properties of small, high-contrast structures has far-reaching implications. In the realm of linear optics, near-zero scattering can lead to the development of advanced camouflage technologies, improved optical components, and novel sensing devices. For instance, the groundbreaking work of Stefan Hell, a Nobel laureate in Chemistry (2014), demonstrated the power of manipulating light scattering to achieve super-resolution microscopy, breaking the diffraction limit and enabling unprecedented visualization of biological structures.

However, the incorporation of nonlinearity, particularly the Kerr effect, opens up new avenues for dynamic control and tunability of scattering properties. This enables the creation of “smart” materials and devices with adaptable optical responses, further expanding the potential applications in areas such as optical switching, signal processing, and nonlinear microscopy. Moreover, the fascinating phenomenon of superlensing, achievable with negative index materials, offers the possibility of surpassing the diffraction limit and achieving perfect imaging. Deriving an effective refractive index formula for complex multilayered structures is crucial for understanding and predicting their optical behavior. Effective medium theory provides a powerful framework for describing the macroscopic properties of composite materials based on their microscopic constituents. However, extending these theories to high-contrast media with nonlinear responses requires careful consideration of the interplay between material properties, geometry, and the strength of the nonlinearity.

Developing accurate effective refractive index formulas for such complex configurations is essential for the design and optimization of novel optical and acoustic devices with tailored scattering properties. EXAMPLE 1 demonstrates how the derived mathematical framework for analyzing near-zero scattering in both linear and nonlinear high-contrast media can be used as a solution to this technical problem. Specifically, EXAMPLE 1 shows how a derived asymptotic formula can be used to evaluate resonances of small, arbitrarily shaped scatterers, elucidating their dependence on material properties, geometry, and the strength of the Kerr nonlinearity. EXAMPLE 1 also shows how a derived effective refractive index formula can be used to evaluate multilayered structures, enabling prediction and control of their scattering response. EXAMPLE 1 further demonstrates how systems employing these formulae can be used for the design and development of advanced optical and acoustic devices with tailored scattering properties.

Resonances in Small, Double Layered, High-Contrast, Nonlinear Scatterers with Arbitrary Geometry

Consider a small volume high contrast nonlinear medium exhibiting Kerr effect of arbitrary geometry. The governing equation is:

$$Δ u + {k}^{2} ( 1 + η ( x ) ) u + {k}^{2} β ( x ) {\vert u \vert}^{2} u = 0$$

subject to Sommerfeld radiation condition at infinity.

k is the wave number, η is the medium susceptibility coefficient, and u is the scalar field. λ=k² is the spectral parameter.

### Lippmann-Schwinger Integral Solution is Given by:

$$u ( x ) = {u}_{i} ( x ) + {k}^{2} {\int }_{hB} \frac{{η}_{0} ( y )}{{h}^{2}} G ( x , y ) u ( y ) dy + {k}^{2} {\int }_{hB} \frac{{β}_{0} ( y )}{{h}^{2}} G ( x , y ) {\vert u ( y ) \vert}^{2} u ( y ) dy ,$$

where uᵢ is the incident field and G in 3D is defined as:

$$G ( x , y ) = \frac{1}{4 π} \frac{exp ( i \sqrt{λ} \vert x - y \vert )}{\vert x - y \vert}$$

Setting uᵢ=0, we obtain the integral eigenvalue problem that is nonlinear in both λ and u:

$$λ T ( λ ) u = u .$$

$$T ( λ ) ( u ) ( x ) = \frac{1}{4 π} {\int }_{hB} η ( y ) \frac{exp ( i \sqrt{λ} \vert x - y \vert )}{\vert x - y \vert} u ( y ) dy + \frac{1}{4 π} {\int }_{hB} β ( y ) \frac{exp ( i \sqrt{λ} \vert x - y \vert )}{\vert x - y \vert} {\vert u ( y ) \vert}^{2} u ( y ) dy$$

By scaling the spatial variables and the media properties as follows:

$$η = {χ}_{hB} \frac{{η}_{0}}{{h}^{2}} , \qquad β = {χ}_{hB} \frac{{β}_{0}}{{h}^{2}} , \qquad x = h \tilde{x} , \qquad y = h \tilde{y}$$

$${λ}_{h} {T}_{h} ( {λ}_{h} ) {u}_{h} = {u}_{h}$$

$${T}_{h} ( λ ) ( u ) ( \tilde{x} ) = \frac{1}{4 π} {\int }_{B} {η}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) d \tilde{y} + \frac{1}{4 π} {\int }_{B} {β}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) {\vert u ( \tilde{y} ) \vert}^{2} d \tilde{y}$$

The associated limiting eigenvalue problem, as h→0 is:

$${λ}_{0} {T}_{0} ( {λ}_{0} ) {u}_{0} = {u}_{0} ,$$

$${T}_{0} ( u ) ( \tilde{x} ) = \frac{1}{4 π} {\int }_{B} {η}_{0} ( 0 ) \frac{u ( \tilde{y} )}{\vert \tilde{x} - \tilde{y} \vert} d \tilde{y} + \frac{1}{4 π} {\int }_{B} {β}_{0} ( 0 ) \frac{u ( \tilde{y} )}{\vert \tilde{x} - \tilde{y} \vert} {\vert u ( \tilde{y} ) \vert}^{2} d \tilde{y}$$

Now that Tₕ and T₀ are well defined, we can compute the asymptotic formula by executing the inner product in the formula:

$${λ}_{h} = {λ}_{0} + {λ}_{0}^{2} ( ( {T}_{0} - {T}_{h} ( {λ}_{0} ) ) {u}_{0} , {u}_{0} ) + 𝒪 ( {h}^{2} )$$

T₀ is a self-adjoint compact operator with positive eigenvalues. Performing Taylor expansion on the functions:

$$h ↦ {η}_{0} ( h \tilde{y} ) \frac{exp ( i \sqrt{λ} h \vert \tilde{x} - \tilde{y} \vert )}{\vert \tilde{x} - \tilde{y} \vert} and h ↦ {β}_{0} ( h \tilde{y} ) \frac{exp ( i \sqrt{λ} h \vert \tilde{x} - \tilde{y} \vert )}{\vert \tilde{x} - \tilde{y} \vert}$$

gives a first order approximation of the resonances. Let

$${U}_{0} = {\int }_{B} {u}_{0} ( x ) dx , and {u}_{h} = {u}_{0} + {u}_{1} h + o ( h )$$

The value λ₁ in λₕ=λ₁h+O(h²) is given by:

$$- 4 {πλ}_{1} = 2 {β}_{0} ( 0 ) {λ}_{0}^{2} {\int }_{B} {\int }_{B} \frac{{u}_{0} ( y ) Re ( {u}_{1} ( y ) )}{\vert x - y \vert} {u}_{0} ( x ) dydx + {λ}_{0}^{2} {\int }_{B} {\int }_{B} \frac{∇ {η}_{0} ( 0 ) \cdot {yu}_{0} ( y )}{\vert x - y \vert} {u}_{0} ( x ) dydx + i \text{?} {η}_{0} ( 0 ) {U}_{0}^{2} + {λ}_{0}^{2} {\int }_{B} {\int }_{B} \frac{∇ {β}_{0} ( 0 ) \cdot {yu}_{0}^{3} ( y )}{\vert x - y \vert} {u}_{0} ( x ) dydx + i \text{?} {β}_{0} ( 0 ) {U}_{0} {\int }_{B} {u}_{0}^{3} ( y ) dy$$

$$\text{?} \text{indicates text missing or illegible when filed}$$

Re(u₁) obeys:

$$4 π Re ( {u}_{1} ( x ) ) = {λ}_{0} {\int }_{B} \frac{∇ {η}_{0} \cdot {yu}_{0} + ∇ {β}_{0} \cdot {yu}_{0}^{3}}{\vert x - y \vert} dy + {λ}_{0} {\int }_{B} \frac{Re ( {u}_{1} )}{\vert x - y \vert} ( {η}_{0} + 3 {β}_{0} {u}_{0}^{2} ) dy - \frac{{λ}_{0}}{4 π} {u}_{0} ( x ) ( 2 {β}_{0} ( 0 ) {\int }_{B} {\int }_{B} \frac{{u}_{0} ( y ) Re ( {u}_{1} ( y ) )}{\vert x - y \vert} {u}_{0} ( x ) dydx + {\int }_{B} {\int }_{B} \frac{∇ {η}_{0} ( 0 ) \cdot {yu}_{0} ( y )}{\vert x - y \vert} {u}_{0} ( x ) dydx + {\int }_{B} {\int }_{B} \frac{∇ {β}_{0} ( 0 ) \cdot {yu}_{0}^{3} ( y )}{\vert x - y \vert} dydx )$$

When η₀ and β₀ are constants.

$$- 4 {πλ}_{1} = 2 {β}_{0} {λ}_{0}^{2} {\int }_{B} {\int }_{B} \frac{{u}_{0} ( y ) Re ( {u}_{1} )}{\vert x - y \vert} {u}_{0} ( x ) dydx + i \text{?} {η}_{0} {U}_{0}^{2} + i \text{?} {β}_{0} {U}_{0} {U}_{1}$$

$${U}_{0} = {\int }_{B} {u}_{0} ( x ) dx , {U}_{1} = {\int }_{B} {{u}_{0} ( x )}^{3} dx$$

$$4 π R e ( {u}_{1} ( x ) ) = {λ}_{0} {\int }_{B} \frac{Re ( {u}_{1} )}{\vert x - y \vert} ( {η}_{0} + 3 {β}_{0} {u}_{0}^{2} ) dy - \frac{{λ}_{0}}{4 π} 2 {β}_{0} {u}_{0} ( x ) {\int }_{B} {\int }_{B} \frac{{u}_{0} ( y ) R e ( {u}_{1} )}{\vert x - y \vert} {u}_{0} ( x ) dydx .$$

$$\text{?} \text{indicates text missing or illegible when filed}$$

In the specific case of a spherical scatterer, we found that R(u₁) vanishes, e.g., R(u₁)=0.

While the equations presented above may appear complex and potentially challenging to implement due to the non-constant nature of η and β, and the arbitrary geometry involved, it often simplifies significantly in practical physical scenarios as will be explained below.

### Case 1. Single-Layer Kerr Effect

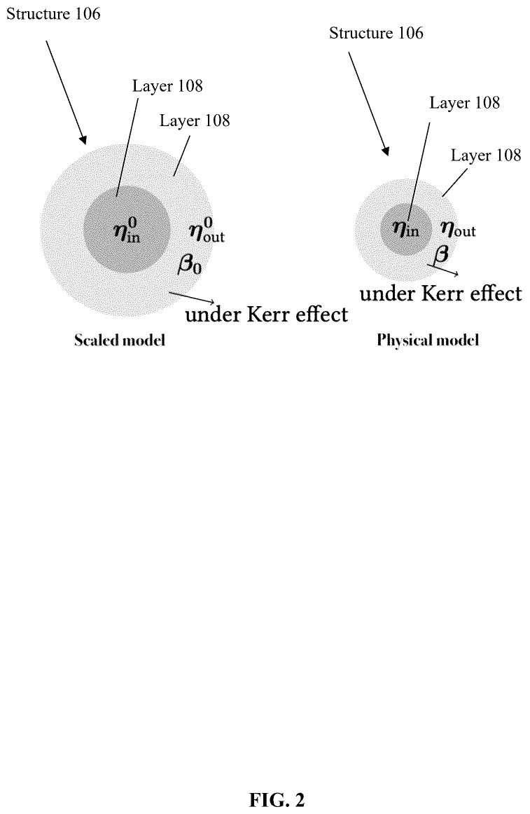

Referring to FIG. 2, consider the scattering problem of high contrast small volume, hB. The small scatterer has two concentric inner and outer layers, with the latter exhibiting nonlinear Kerr effect.

$$hB = {hB}_{i n} ⋃ {hB}_{out}$$

$$η ( x ) = {χ}_{h} {B}_{i n} ( x ) {η}_{i n} + {χ}_{h} {B}_{i n} ( x ) {η}_{out} = {χ}_{h} {B}_{i n} \frac{{η}_{i n}}{{h}^{2}} + {χ}_{h} {B}_{out} \frac{{η}_{out}}{{h}^{2}}$$

$$β ( x ) = {χ}_{h} {B}_{out} \frac{{β}_{0}}{{h}^{2}}$$

for constant η₀ and β₀.

Within the context of this new configuration:

$${T}_{h} ( λ ) ( u ) ( x ) = \frac{{η}_{i n}^{0}}{4 π} {\int }_{{B}_{i n}} \frac{exp ( i \sqrt{λ} h \vert x - y \vert )}{\vert x - y \vert} u ( y ) dy + \frac{{η}_{out}^{0}}{4 π} {\int }_{{B}_{out}} \frac{exp ( i \sqrt{λ} h \vert x - y \vert )}{\vert x - y \vert} u ( y ) dy + \frac{{β}_{0}}{4 π} {\int }_{{B}_{out}} \frac{exp ( i \sqrt{λ} h \vert x - y \vert )}{\vert x - y \vert} u ( y ) {\vert u ( y ) \vert}^{2} dy$$

Hence we define the limiting operator, T₀, as h→0 as:

$${T}_{0} ( λ ) ( u ) ( x ) = \frac{{η}_{i n}^{0}}{4 π} {\int }_{{B}_{i n}} \frac{u ( y )}{\vert x - y \vert} dy + \frac{{η}_{out}^{0}}{4 π} {\int }_{{B}_{out}} \frac{u ( y )}{\vert x - y \vert} dy + \frac{{β}_{0}}{4 π} {\int }_{{B}_{out}} \frac{u ( y )}{\vert x - y \vert} {\vert u ( y ) \vert}^{2} dy$$

When solving for the resonances, λₕ, the eigenvalue problem λₕTₕ uₕ=uₕ via the limiting eigenvalue problem λ₀T₀u₀=u₀. In other words, we first solve the easier latter equation for u₀ and λ₀. Now let us expand Tₕ by performing Taylor expansion:

$$h ↦ exp ( i \sqrt{λ} h \vert x - y \vert )$$

$${T}_{h} ( λ ) ( u ) ( x ) = {T}_{0} ( λ ) ( u ) ( x ) + \frac{i \sqrt{λ} h}{4 π} ( {η}_{i n}^{0} {\int }_{{B}_{i n}} u ( y ) dy + {η}_{out}^{0} {\int }_{{B}_{out}} u ( y ) dy + {β}_{0} {\int }_{{B}_{out}} u ( y ) {\vert u ( y ) \vert}^{2} dy ) + 𝒪 ( {h}^{2} )$$

Evaluating at u₀ and λ₀ we obtain:

$$( {T}_{0} - {T}_{h} ( {λ}_{0} ) ) {u}_{0} = - \frac{i \sqrt{{λ}_{0}} h}{4 π} ( {η}_{i n}^{0} {\int }_{{B}_{i n}} {u}_{0} ( y ) dy + {η}_{out}^{0} {\int }_{{B}_{out}} {u}_{0} ( y ) dy + {β}_{0} {\int }_{{B}_{out}} {u}_{0}^{3} ( y ) dy ) + 𝒪 ( {h}^{2} )$$

$$( {T}_{0} - {T}_{h} ( {λ}_{0} ) ) {u}_{0} = - \frac{i \sqrt{{λ}_{0}} h}{4 π} ( {η}_{i n}^{0} {U}_{i n} + {η}_{out}^{0} {U}_{out} + {β}_{0} {U}_{out β} ) + 𝒪 ( {h}^{2} )$$

$${U}_{i n} = {\int }_{{B}_{i n}} {u}_{0} ( y ) dy , {U}_{out} = {\int }_{{B}_{out}} {u}_{0} ( y ) dy$$

$${U}_{out β} = {\int }_{{B}_{out}} {u}_{0}^{3} ( y ) dy$$

At this point, we are ready to compute λ_{I} by executing the expansion asymptotic formula:

$${λ}_{h} = {λ}_{0} + {λ}_{0}^{2} 〈 ( {T}_{0} - {T}_{h} ( {λ}_{0} ) ) {u}_{0} , {u}_{0} 〉 + 𝒪 ( {h}^{2} )$$

$$Let$$

$${λ}_{h} = {λ}_{0} + {λ}_{1} h + 𝒪 ( {h}^{2} )$$

It follows that the correction λ₁ is:

$${λ}_{1} = - \frac{i {λ}_{0}^{\frac{5}{2}}}{4 π} ( {η}_{i n}^{0} {U}_{i n} + {η}_{out}^{0} {U}_{out} + {β}_{0} {U}_{out β} ) {U}_{0}$$

$${U}_{0} = {\int }_{B} {u}_{0} ( y ) dy$$

### Case 2: Dual-Layer Kerr Effect

Referring to FIG. 2, this configuration offers greater flexibility in designing the 3D scatterer, allowing for scenarios with either distinct or identical susceptibility coefficients (ηᵢₙ≠ηₒᵤₜ or ηᵢₙ=ηₒᵤₜ) and Kerr coefficients (βᵢₙ≠βₒᵤₜ or βᵢₙ=βₒᵤₜ). All coefficients are assumed to be constant.

$$β ( x ) = {χ}_{h} {B}_{i n} \frac{{β}_{i n}^{0}}{{h}^{2}} + {χ}_{h} {B}_{out} \frac{{β}_{out}^{0}}{{h}^{2}}$$

$${T}_{h} ( λ ) ( u ) ( x ) = \frac{{η}_{i n}^{0}}{4 π} {\int }_{{B}_{i n}} \frac{exp ( i \sqrt{λ} h \vert x - y \vert )}{\vert x - y \vert} u ( y ) dy + \frac{{η}_{out}^{0}}{4 π} {\int }_{{B}_{out}} \frac{exp ( i \sqrt{λ} h \vert x - y \vert )}{\vert x - y \vert} u ( y ) dy + \frac{{β}_{i n}^{0}}{4 π} {\int }_{{B}_{i n}} \frac{exp ( i \sqrt{λ} h \vert x - y \vert )}{\vert x - y \vert} u ( y ) {\vert u ( y ) \vert}^{2} dy + \frac{{β}_{out}^{0}}{4 π} {\int }_{{B}_{out}} \frac{exp ( i \sqrt{λ} h \vert x - y \vert )}{\vert x - y \vert} u ( y ) {\vert u ( y ) \vert}^{2} dy$$

$${T}_{h} ( λ ) ( u ) ( x ) = \frac{{η}_{i n}^{0}}{4 π} {\int }_{{B}_{i n}} \frac{u ( y )}{\vert x - y \vert} dy + \frac{{η}_{out}^{0}}{4 π} {\int }_{{B}_{out}} \frac{u ( y )}{\vert x - y \vert} dy + \frac{{β}_{i n}^{0}}{4 π} {\int }_{{B}_{i n}} \frac{u ( y )}{\vert x - y \vert} {\vert u ( y ) \vert}^{2} dy + \frac{{β}_{out}^{0}}{4 π} {\int }_{{B}_{out}} \frac{u ( y )}{\vert x - y \vert} {\vert u ( y ) \vert}^{2} dy$$

With the Taylor expansion of

$$h ↦ exp ( i \sqrt{λ} h \vert x - y \vert )$$

$${T}_{h} ( λ ) ( u ) ( x ) = {T}_{0} ( λ ) ( u ) ( x ) + \frac{i \sqrt{λ} h}{4 π} ( {η}_{i n}^{0} {\int }_{{B}_{i n}} u ( y ) dy + {η}_{out}^{0} {\int }_{{B}_{out}} u ( y ) dy + {β}_{i n}^{0} {\int }_{{B}_{i n}} u ( y ) {\vert u ( y ) \vert}^{2} dy + {β}_{out}^{0} {\int }_{{B}_{out}} u ( y ) {\vert u ( y ) \vert}^{2} dy ) + 𝒪 ( {h}^{2} )$$

The correction λ₁ is:

$${λ}_{1} = - \frac{i {λ}_{0}^{\frac{5}{2}}}{4 π} ( {η}_{i n}^{0} {U}_{i n} + {η}_{out}^{0} {U}_{out} + {β}_{i n}^{0} {U}_{i n β} + {β}_{out}^{0} {U}_{out β} ) {U}_{0}$$

$${U}_{i n β} = {\int }_{{B}_{i n}} {u}_{0}^{3} ( y ) dy , {U}_{out β} = {\int }_{{B}_{out}} {u}_{0}^{3} ( y ) dy$$

$${U}_{i n} = {\int }_{{B}_{i n}} {u}_{0} ( y ) dy , {U}_{out} = {\int }_{{B}_{out}} {u}_{0} ( y ) dy , and {U}_{0} = {\int }_{B} {u}_{0} ( y ) dy$$

Note that we recover λ₁ in case 1 by setting β⁰ᵢₙ=0. Furthermore, setting β⁰ₒᵤₜ=0 provides the formula for λ₁ when only the inner layer exhibits the Kerr effect.

Resonances in Small, Multilayered, High-Contrast, Nonlinear Scatterers with Arbitrary Geometry

Suppose Bₕ is a composite that is optically inhomogeneous with n layers of concentric high contrast media {Bₜ}_{1≤i≤n}, such that:

$$hB = {⋃}_{i = 1}^{i = n} {hB}_{i} ,$$

$$η ( x ) = {\sum }_{i = 1}^{i = n} {χ}_{h} {B}_{i} ( x ) {η}^{i} = {\sum }_{i = 1}^{i = n} {χ}_{h} {B}_{i} ( x ) \frac{{η}_{0}^{i}}{{h}^{2}} ,$$

$$β ( x ) = {\sum }_{i = 1}^{i = n} {χ}_{h} {B}_{i} ( x ) {β}^{i} = {\sum }_{i = 1}^{i = n} {χ}_{h} {B}_{i} ( x ) \frac{{β}_{0}^{i}}{{h}^{2}} ,$$

$${η}_{0} ( x ) = {\sum }_{i = 1}^{i = n} {χ}_{h} {B}_{i} ( x ) {η}_{0}^{i} , {β}_{0} ( x ) = {\sum }_{i = 1}^{i = n} {χ}_{h} {B}_{i} ( x ) {β}_{0}^{i}$$

$${T}_{h} ( u ) ( x ) ( λ ) = {\sum }_{k = 1}^{k = n} \frac{{η}_{0}^{k}}{4 π} {\int }_{{B}_{k}} \frac{exp ( i \sqrt{λ} h \vert x - y \vert )}{\vert x - y \vert} u ( y ) dy + \frac{{β}_{0}^{k}}{4 π} {\int }_{{B}_{k}} \frac{exp ( i \sqrt{λ} h \vert x - y \vert )}{\vert x - y \vert} u ( y ) {\vert u ( y ) \vert}^{2} dy$$

$${T}_{0} ( u ) ( x ) = {\sum }_{k = 1}^{k = n} \frac{{η}_{0}^{k}}{4 π} {\int }_{{B}_{k}} \frac{1}{\vert x - y \vert} u ( y ) dy + \frac{{β}_{0}^{k}}{4 π} {\int }_{{B}_{k}} \frac{1}{\vert x - y \vert} u ( y ) {\vert u ( y ) \vert}^{2} dy$$

### With the Taylor Expansion of:

$$h ↦ exp ( i \sqrt{λ} h \vert x - y \vert ) \\ {T}_{h} ( λ ) ( u ) ( x ) = {T}_{0} ( λ ) ( u ) ( x ) + \frac{i \sqrt{λ} h}{4 π} ( {\sum }_{k = 1}^{n} {η}_{0}^{k} {\int }_{{B}_{k}} u ( y ) dy + {β}_{0}^{k} {\int }_{{B}_{k}} u ( y ) {\vert u ( y ) \vert}^{2} dy + ) + 𝒪 ( {h}^{2} ) \\ {λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) \\ U = {\int }_{B} {u}_{0} ( x ) dx , \\ {U}_{k} = {\int }_{{B}_{k}} {u}_{0} ( x ) dx , {U}_{k}^{β} = {\int }_{{B}_{k}} {u}_{0}^{3} ( x ) dx , 1 \leq k \leq n$$

### Application: Near Zero Scattering for High Contrast Small Multilayered Volume

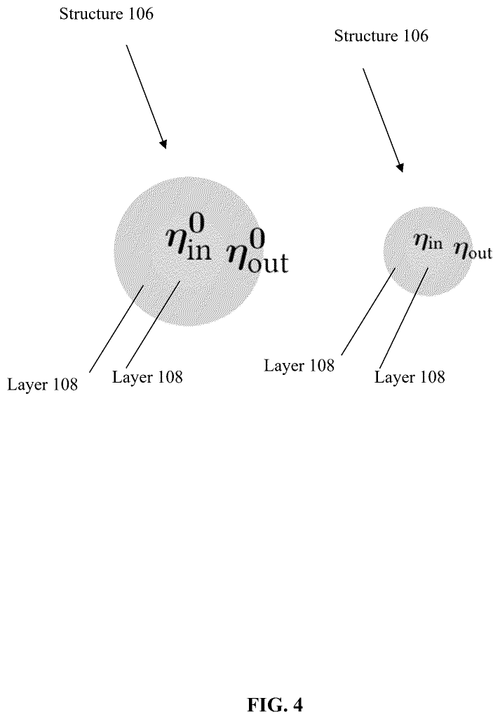

Referring to FIG. 4, to achieve near zero scattering, we suppress the leading correction λ₁ in λₕ≈λ₀+λ₁ₕ to obtain the following as the requirement for near zero scattering for n layers:

$${\sum }_{k = 1}^{n} {η}_{0}^{k} {U}_{k} + {β}_{0}^{k} {U}_{k}^{β} = 0$$

This formula provides multiple configurations each achieving near zero scattering.

Layers Having Negative Index Materials without Kerr Effect Presence

In this case, for near zero scattering requirement for n layers, the formula is as follows due to all β^{k} being zero:

$${\sum }_{k = 1}^{n} {η}_{0}^{k} {U}_{k} = 0$$

This is for n layers, each with a refractive index η^{k}. For example, suppose we have two layers where one of the layers has a negative refractive index. We can tune the design of the structure according to the formula:

$${η}_{in}^{0} {\int }_{{B}_{in}} {u}_{0} ( y ) dy + {η}_{out}^{0} {\int }_{{B}_{out}} {u}_{0} ( y ) dy = 0$$

The near zero scattering requirement for two layers is:

$${η}_{in}^{0} {\int }_{{B}_{in}} {u}_{0} ( y ) dy + {η}_{out}^{0} {\int }_{{B}_{out}} {u}_{0} ( y ) dy = 0$$

For instance, if ηᵢₙ=−ηₒᵤₜ, then we should design the geometry to satisfy:

$${\int }_{{B}_{in}} {u}_{0} ( y ) dy = {\int }_{{B}_{out}} {u}_{0} ( y ) dy$$

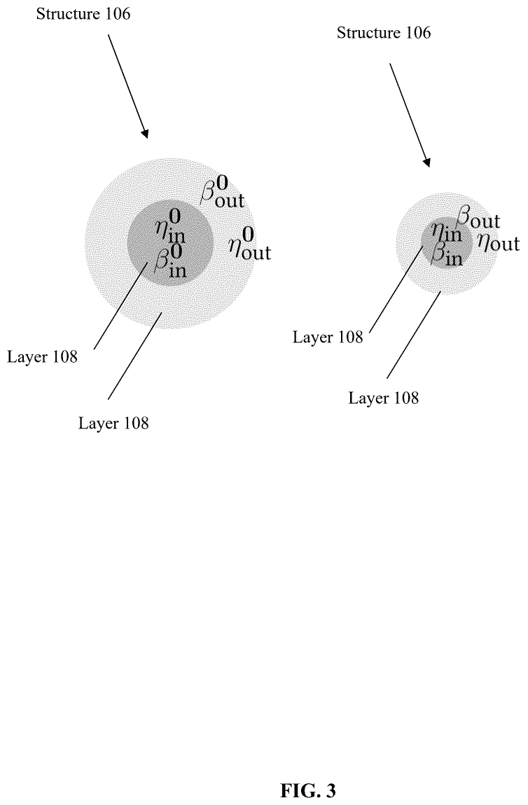

Layers Having Negative Index Materials With Kerr Effect Presence, β^{k}>0 (see FIG. 3)

In this case, can be used as a toning factor to achieve λ₁=0. For example, if both layers have the Kerr effect then the near zero scattering formula writes:

$${η}_{in}^{0} {U}_{in} + {η}_{out}^{0} {U}_{out} + {β}_{in}^{0} {U}_{in β} + {β}_{out}^{0} {U}_{out β} = 0$$

Notably, one or both layers can have a negative refractive index.

Layers Having Positive Index Materials With Kerr Effect Presence, η^{k}>0, β^{k}<0

This is the most revolutionary case. The presence of negative Kerr coefficients in certain semiconductors and graphene significantly expands options for crafting negative index materials. Harnessing this unique property opens exciting new avenues for research and development in this field. The mathematical derivations provide essential insights into the underlying mechanisms and offer guidance for the practical realization of these novel materials. To achieve the desired effect, at least one layer must possess a negative Kerr coefficient of sufficient magnitude to counterbalance the positive terms. This configuration mitigates the need for negative index materials, which can be more complex and costly to fabricate than media with negative Kerr coefficients.

The near zero scattering requirement for n layers is:

$${\sum }_{k = 1}^{n} {η}_{0}^{k} {U}_{k} + {β}_{0}^{k} {U}_{k}^{β} = 0$$

Now, it is the Kerr coefficients β^{k} that play a crucial role in nullifying λ₁. This formula offers remarkable flexibility in tailoring the scatterer design by enabling the selection of appropriate shapes and the number of layers needed for precise tuning.

### Constant Refractive Index and Kerr Effect Coefficient, η>0 and β<0

While this is the most basic case, it is still a complex problem to design a one layer 3D medium with near zero scattering and a sub-case to design a negative refractive index medium. A near zero scattering (e.g., near zero scattering requirement for one layer) is achieved by satisfying:

$${η}_{0} {\int }_{B} {u}_{0} ( y ) dy + {β}_{0} {\int }_{B} {u}_{0}^{3} ( y ) dy = 0$$

Crafting a negative index material with one layer exhibiting a negative Kerr effect (e.g., design of negative index material using negative Kerr effect coefficient) should follow the expression:

$${η}_{0} {\int }_{B} {u}_{0} ( y ) dy + {β}_{0} {\int }_{B} {u}_{0}^{3} ( y ) dy < 0$$

where η₀>0.

The effective refractive index, η_{eff}, can be approximated.

The effective refractive index for high contrast small volume with negative Kerr effect would be:

$${η}_{eff} \approx \frac{η {U}_{0} + β {U}_{1}}{{U}_{0}} \\ {U}_{0} {\int }_{B} {u}_{0} ( x ) dx and {U}_{1} = {\int }_{B} {u}_{0}^{3} ( x ) dx$$

This holds irrespective of the signs of η and β. Thus, to achieve a specific refractive index, whether positive or negative, η and β can be adjusted accordingly.

The effective refractive index for high contrast small volume with n layers would be:

$${η}_{eff} \approx \frac{{\sum }_{k = 1}^{n} {η}^{k} {U}_{k} + {β}^{k} {U}_{k}^{β}}{{U}_{0}}$$

Suppose Bₕ is a composite and is optically inhomogeneous with n layers of concentric small high contrast media {Bᵢ}_{1≤i≤n} with arbitrary geometry, such that:

$$hB = {⋃}_{i = 1}^{i = n} {hB}_{i} , {B}_{i} = {hB}_{i}^{0} \\ η ( x ) = {\sum }_{i = 1}^{i = n} χ {hB}_{i} ( x ) {η}^{i} = {\sum }_{i = 1}^{i = n} χ {hB}_{i} ( x ) \frac{{η}_{0}^{i}}{{h}^{2}} , \\ β ( x ) = {\sum }_{i = 1}^{i = n} χ {hB}_{i} ( x ) {β}^{i} = {\sum }_{i = 1}^{i = n} χ {hB}_{i} ( x ) \frac{{β}_{0}^{i}}{{h}^{2}} , \\ {η}_{0} ( x ) = {\sum }_{i = 1}^{i = n} χ {B}_{i} ( x ) {η}_{0}^{i} , {β}_{0} ( x ) = {\sum }_{i = 1}^{i = n} χ {B}_{i} ( x ) {β}_{0}^{i}$$

To achieve near zero scattering for n layers:

$${\sum }_{k = 1}^{n} {η}_{0}^{k} {U}_{k} + {β}_{0}^{k} {U}_{k}^{β} = 0$$

This can be achieved by leveraging either negative refractive index materials, negative Kerr effect media, or a combination of both. Furthermore, the geometry can be tailored accordingly to optimize the desired scattering response, as this formula applies to arbitrary shapes. To achieve a target refractive index (e.g., effective refractive index for high contrast small volume with n layers), whether positive or negative, the media parameters can be tailored to satisfy the following equation:

$${η}_{eff} \approx \frac{{\sum }_{k = 1}^{n} {η}^{k} {U}_{k} + {β}^{k} {U}_{k}^{β}}{{U}_{0}}$$

These derivations unveil a remarkable opportunity to generate a vast array of scattering patterns by strategically manipulating the arrangement, properties, and number of layers. This opens a rich landscape for exploration and innovation, with potential applications spanning various fields, from photonics and acoustics to medical imaging and beyond.

### Example 2

Scattering resonances play a crucial role in understanding wave behavior in various physical systems. While significant progress has been made in analyzing resonances in high-contrast and nonlinear media, a general characterization of resonances in small, high-contrast nonlinear media with the Kerr effect, particularly in layered configurations, has remained an open problem. EXAMPLE 2 presents an asymptotic approach that addresses this gap by providing an approximation for resonances in terms of material properties, geometry, and nonlinearity. Our results offer new insights into the dependence of resonances on these factors, particularly for complex multilayered structures, making this the first general characterization of its kind. The formulas presented in this work lay a new theoretical foundation for the study of high-contrast, nanoscale resonances and nonlinear effects in layered media. Given their broad applicability across nanophotonics and advanced materials science, these results can be used for shaping future developments in the field, analogous to the role of fundamental equations in other scientific domains.

The study of scattering resonances in high-contrast media has attracted considerable attention due to its broad implications across various scientific and technological disciplines. These resonances, originating from the interaction of waves with material interfaces and inhomogeneities, underpin a wide range of phenomena, including light trapping in solar cells (Zhou & Biswas, 2010), sound absorption in acoustic metamaterials (Cummer et al., 2016), and the manipulation of electromagnetic waves in advanced communication systems (Alu & Engheta, 2007).

The ability to fabricate structures with intricate geometries and tailored optical properties has expanded significantly in recent years, thanks to advancements in material science and nanotechnology. However, analyzing wave propagation and resonance behavior in such complex systems often demands computationally intensive numerical simulations. Asymptotic methods, which offer approximate solutions in specific regimes, present a powerful alternative for gaining insights into these phenomena without relying on extensive numerical computations.

EXAMPLE 2 demonstrated development of an asymptotic approach to characterize scattering resonances in small, high-contrast nonlinear optical multilayered media exhibiting the Kerr effect. This nonlinearity, where the scattering resonances depend on both the refractive index and the intensity of the incident light, introduces an additional layer of complexity to the problem. One objective is to derive an approximation for the resonances that illuminates their dependence on material properties, geometry, and the strength of the nonlinearity, particularly in the context of layered structures.

Prior research has explored resonances in high-contrast media using a variety of techniques. The first rigorous quantification of these resonances, in both linear and nonlinear regimes, was presented in (Meklachi et al., 2018), where a scaling approach and Lippmann-Schwinger integral solution to the Helmholtz equation were employed for a single volume. This work was subsequently extended in (Meklachi, 2022) to cover small, high-contrast, multilayered linear media. Additionally, Ammari et al. (Ammari et al., 2018) established a mathematical framework for analyzing resonances in subwavelength resonator structures, primarily focusing on the linear regime. The influence of nonlinearity on resonance behavior has been investigated in several studies. For example, Moskow (Moskow, 2015) examined nonlinear eigenvalue approximation for compact operators, providing a theoretical foundation for analyzing resonances in nonlinear systems. The work by Ammari et al. (Ammari et al., 2022) further extended these concepts to the context of high-contrast plasmonic media, employing layer potential techniques to approximate resonances.

Moreover, the study of resonances in nonlinear optical media has been a subject of active research. The Kerr effect has been extensively investigated due to its role in phenomena like self-focusing, soliton formation, and optical bistability (Boyd, 2020). Theoretical and numerical studies have explored the impact of the Kerr nonlinearity on resonance frequencies and mode profiles in various configurations (Poutrina et al., 2010; Suchkov et al., 2000).

While these previous works have significantly advanced our understanding of resonances in high-contrast and nonlinear media, a general characterization of resonances in small, high-contrast nonlinear media with Kerr effect, especially in layered configurations, remains an open problem. EXAMPLE 2 bridges this gap by providing an asymptotic approximation that encapsulates the essential physics of the problem. We build upon the foundations laid by previous research, extending them to incorporate the nonlinear Kerr effect and providing a more comprehensive understanding of resonance phenomena in these complex systems.

The potential applications of our research are vast and diverse. In the domain of photonics, our findings could facilitate the design of novel metamaterials with exotic optical properties, enabling advancements in optical sensing, light manipulation, and energy harvesting (Soukoulis & Wegener, 2011). In the realm of acoustics, the ability to precisely control resonances in small structures could lead to the development of acoustic metamaterials with superior sound control capabilities, impacting noise reduction and architectural acoustics (Ma et al., 2014). Furthermore, our work could have ramifications for medical imaging (Dabrowski et al., 2020), where resonant nanoparticles could function as contrast agents or enable targeted drug delivery (Kircher et al., 2014). In electronics and telecommunications, a deeper understanding of resonances could lead to the design of smaller, more efficient antennas and improved electromagnetic shielding (Alitalo & Koppens, 2015). Finally, our research could contribute to the development of more efficient energy harvesting and conversion devices, such as solar cells and thermoelectric devices (Atwater & Polman, 2010).

Resonances in Small, Multilayered, High-Contrast, Nonlinear Scatterers with Arbitrary Geometry

### The Original Work

We build upon the results in (Meklachi et al., 2018) by using aspects of the solution method to compute the new formulae.

Consider a small volume high contrast nonlinear medium exhibiting Kerr effect of arbitrary geometry. The governing equation is:

$$Δ u + {k}^{2} ( 1 + η ( x ) ) u + {k}^{2} β ( x ) {\vert u \vert}^{2} u = 0$$

subject to Sommerfeld radiation condition at infinity.

k is the wave number, η is the medium susceptibility coefficient, and u is the scalar field. Here, λ=k² is the spectral parameter.

Lippmann-Schwinger Integral solution translate to the integral eigenvalue problem that is nonlinear in both λ and u:

$$λ T ( λ ) u = u$$

$$where$$

$$T ( λ ) ( u ) ( x ) = \frac{1}{4 π} {\int }_{hB} η ( y ) \frac{exp ( i \sqrt{λ} \vert x - y \vert )}{\vert x - y \vert} u ( y ) dy + \frac{1}{4 π} {\int }_{hB} β ( y ) \frac{exp ( i \sqrt{λ} \vert x - y \vert )}{\vert x - y \vert} {\vert u ( y ) \vert}^{2} u ( y ) dy$$

By scaling the spatial variables and the media properties as follows:

$$η = {χ}_{hB} \frac{{η}_{0}}{{h}^{2}} ,$$

$$β = {χ}_{hB} \frac{{β}_{0}}{{h}^{2}} ,$$

$$x = h \tilde{x} ,$$

$$y = h \tilde{y}$$

we obtain:

$${λ}_{h} {T}_{h} ( {λ}_{h} ) {u}_{h} = {u}_{h}$$

$$where$$

$${T}_{h} ( λ ) ( u ) ( \tilde{x} ) = \frac{1}{4 π} {\int }_{B} {η}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) d \tilde{y} + \frac{1}{4 π} {\int }_{B} {β}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) {\vert u ( \tilde{y} ) \vert}^{2} d \tilde{y}$$

The associated limiting eigenvalue problem, as h→0 is:

$${λ}_{0} {T}_{0} ( {λ}_{0} ) {u}_{0} = {u}_{0} ,$$

$$where$$

$${T}_{0} ( u ) ( \tilde{x} ) = \frac{1}{4 π} {\int }_{B} {η}_{0} ( 0 ) \frac{u ( \tilde{y} )}{\vert \tilde{x} - \tilde{y} \vert} d \tilde{y} + \frac{1}{4 π} {\int }_{B} {β}_{0} ( 0 ) \frac{u ( \tilde{y} )}{\vert \tilde{x} - \tilde{y} \vert} {\vert u ( \tilde{y} ) \vert}^{2} d \tilde{y}$$

Now that Tₕ and T₀ are well defined, we can compute the asymptotic formula by executing the inner product in the formula:

$${λ}_{h} = {λ}_{0} + {λ}_{0}^{2} 〈 ( {T}_{0} - {T}_{h} ( {λ}_{0} ) ) {u}_{0} , {u}_{0} 〉 + 𝒪 ( {h}^{2} )$$

### Generalized Framework for Linear and Nonlinear Multilayered High-contrast Scatterers With Arbitrary Geometry

Suppose Bₕ is a composite and is optically inhomogeneous with n layers of concentric high contrast media {Bᵢ}_{1≤i≤n}, such that:

$$hB = {⋃}_{i = 1}^{i = n} {hB}_{i} ,$$

$$η ( x ) = {\sum }_{i = 1}^{i = n} {χ}_{{hB}_{i}} ( x ) {η}^{i} = {\sum }_{i = 1}^{i = n} {χ}_{{hB}_{i}} ( x ) \frac{{η}_{0}^{i}}{{h}^{2}} ,$$

$$β ( x ) = {\sum }_{i = 1}^{i = n} {χ}_{{hB}_{i}} ( x ) {β}^{i} = {\sum }_{i = 1}^{i = n} {χ}_{{hB}_{i}} ( x ) \frac{{β}_{0}^{i}}{{h}^{2}} ,$$

$${η}_{0} ( x ) = {\sum }_{i = 1}^{i = n} {χ}_{{B}_{i}} ( x ) {η}_{0}^{i} , {β}_{0} ( x ) = {\sum }_{i = 1}^{i = n} {χ}_{{B}_{i}} ( x ) {β}_{0}^{i}$$

Similar to the previous cases, the operators Tₕ and T₀ write:

$${T}_{h} ( u ) ( x ) ( λ ) = {\sum }_{k = 1}^{k = n} \frac{{η}_{0}^{k}}{4 π} {\int }_{{B}_{k}} \frac{exp ( i \sqrt{λ} h \vert x - y \vert )}{\vert x - y \vert} u ( y ) dy + \frac{{β}_{0}^{k}}{4 π} {\int }_{{B}_{k}} \frac{exp ( i \sqrt{λ} h \vert x - y \vert )}{\vert x - y \vert} u ( y ) {\vert u ( y ) \vert}^{2} dy$$

$${T}_{0} ( u ) ( x ) = {\sum }_{k = 1}^{k = n} \frac{{η}_{0}^{k}}{4 π} {\int }_{{B}_{k}} \frac{1}{\vert x - y \vert} u ( y ) dy + \frac{{β}_{0}^{k}}{4 π} {\int }_{{B}_{k}} \frac{1}{\vert x - y \vert} u ( y ) {\vert u ( y ) \vert}^{2} dy$$

We perform a Taylor expansion of h→exp(i\sqrt{λ}h|x−y|) again, yielding:

$${T}_{h} ( λ ) ( u ) ( x ) = {T}_{0} ( λ ) ( u ) ( x ) + \frac{i \sqrt{λ} h}{4 π} ( {\sum }_{k = 1}^{n} {η}_{0}^{k} {\int }_{{B}_{k}} u ( y ) dy + {β}_{0}^{k} {\int }_{{B}_{k}} u ( y ) {\vert u ( y ) \vert}^{2} dy + ) + 𝒪 ( {h}^{2} )$$

We can now evaluate the equation at u₀ and λ₀, which gives:

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} )$$

$$where$$

$${U}_{0} = {\int }_{B} {u}_{0} ( x ) dx ,$$

$${U}_{k} = {\int }_{{B}_{k}} {u}_{0} ( x ) dx ,$$

$$and$$

$${U}_{k}^{β} = {\int }_{{B}_{k}} {u}_{0}^{3} ( x ) dx , 1 \leq k \leq n .$$

This expression encapsulates the spectral characteristics, specifically the resonance properties, of the multilayered medium in its entirety.

In linear media, in the absence of Kerr effect for example, this formula simply writes:

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} ] h + 𝒪 ( {h}^{2} )$$

which is very useful in the analysis of resonances of composite complex layered high contrast media. The formula provides a wide range of possibilities for the design of many novel configurations, where for a multilayered material, if one layer is desired to be linear, its corresponding Kerr coefficient, βₖ, can be set to zero. The formula can be used as a predictor on how changes in parameters of a media would affect the resonances. There is a plethora of applications for this formula. One of the most remarkable and powerful outcomes is the derivation of the effective refractive index for high-contrast nanoscale linear and nonlinear media, applicable to any number of layers and arbitrary geometries.

### Effective Medium Theory

Effective Medium Theory (EMT) plays a crucial role in bridging microscopic and macroscopic descriptions of wave propagation in complex media, yet determining accurate effective parameters for high-contrast, nonlinear, and multilayered structures remains an open problem with significant implications for advancements in nanophotonics, metamaterials, and quantum optics.

### Effective Susceptibility Coefficient in Linear and Nonlinear Layered Media

The susceptibility η describes how a material polarizes in response to an electric field, impacting the material's ability to transmit or interact with electromagnetic waves. In a layered system, each layer contributes to the total response based on its own susceptibility and the field distribution within it.

For a homogeneous medium with constant susceptibility η₀:

$$\begin{matrix}{λ}_{h} = {λ}_{0} - i \frac{{λ}_{0}^{\frac{5}{2}} {η}_{0}}{4 π} {U}_{0}^{2} h + 𝒪 ( {h}^{2} ) \\ = {λ}_{0} - i \frac{{λ}_{0}^{\frac{5}{2}}}{4 π} {U}_{0} h \cdot ( {η}_{eff}^{0} {U}_{0} ) + 𝒪 ( {h}^{2} )\end{matrix}$$

By matching with the equation above, we derive a general formula for the effective susceptibility coefficient for any number of layers composed of linear or nonlinear high-contrast media at the nanoscale.

$${η}_{eff} = \frac{{\sum }_{k = 1}^{n} {η}^{k} {U}_{k} + {β}^{k} {U}_{k}^{β}}{{U}_{0}}$$

This formula describes the behavior of a wave propagating through layered media, with the effective susceptibility coefficient capturing the combined contributions from multiple layers. The inclusion of nonlinear terms, such as the Kerr nonlinearity (represented by the β-dependent term), accounts for higher-order field interactions. This formulation provides enhanced flexibility in tuning the parameters and geometry of the layers, allowing for precise control over the system's behavior. For instance, not all layers need to exhibit nonlinear properties.

In a strictly linear setting, the formula simplifies by setting all βₖ=0, yielding:

$${η}_{eff} = \frac{{\sum }_{k = 1}^{n} {η}^{k} {U}_{k}}{{U}_{0}}$$

### Effective Refractive Index in Linear and Nonlinear Layered Media

The effective refractive index n_{eff} determines the phase velocity and governs wave propagation in a composite medium. In many optical scenarios, the permittivity μᵣ is approximated by 1. The refractive index depends directly on the susceptibility, expressed as:

$${n}_{eff}^{2} = 1 + {η}_{eff} ,$$

The effective refractive index then writes:

$${n}_{eff} = \sqrt{1 + {η}_{eff}}$$

where η_{eff} is given by the equation discussed above for nonlinear media and simplifies in the case of linear media. The formula for the effective refractive index n_{eff}²=1+η_{eff} plays a crucial role in the analysis and design of optical systems, particularly those involving complex, layered, or nonlinear media. It provides a macroscopic measure that encapsulates the microscopic interactions between electromagnetic waves and material properties. This formula simplifies wave propagation analysis by reducing the need for detailed modeling of individual layers, while still capturing the essential contributions of linear and nonlinear susceptibilities. Moreover, the ability to compute the effective refractive index allows for precise control of wave behavior, enabling applications such as light manipulation, cloaking, and energy concentration.

### Applications

Traditional medium theory fails for small photonic objects due to its inability to account for high material contrasts, nonlinear effects (e.g., the Kerr effect), and geometry-dependent behaviors. These objects often exhibit subwavelength features, localized resonances, and strong near-field interactions that break the assumptions of homogenization and effective medium approximations. The derived effective medium formula offers a simplified scalar approach that rigorously accounts for the given constraints, such as high material contrast and geometric complexities. Notably, it is an exact formula, ensuring precise characterization of the system without relying on approximations typical of traditional medium theories. The newly developed effective medium theory formulas are crucial in nanophotonics and metamaterials, enabling precise control of the effective refractive index and paving the way for breakthroughs in advanced optical devices and technologies.

Engineering Optical Materials with Exotic Properties: The Case of Zero Scattering

Referring to FIG. 2, zero scattering has applications in designing invisible cloaks, reducing radar cross-sections, improving photonic devices, and creating materials with tailored wave propagation properties. The relative permittivity for the scatterer is given by:

$${ϵ}_{r} = 1 + {η}_{eff}$$

Zero scattering is achieved when ϵᵣ=1, which occurs when the scatterer behaves like air. This condition implies the requirement:

$${η}_{eff} = \frac{{\sum }_{k = 1}^{n} {η}^{k} {U}_{k} + {β}^{k} {U}_{k}^{β}}{{U}_{0}} = 0 .$$

Thus, we conclude:

$${\sum }_{k = 1}^{n} {η}^{k} {U}_{k} + {β}^{k} {U}_{k}^{β} = 0 .$$

The same conclusion is demonstrated when the first-order correction coefficient in is set to zero, signifying negligible scattering.

Consider the scattering problem of high contrast small volume, hB. The small scatterer has two concentric inner and outer layers, with the latter exhibiting nonlinear Kerr effect.

$$h B = h {B}_{i n} ⋃ {hB}_{o u t}$$

$$η ( x ) = {χ}_{h {B}_{in}} ( x ) {η}_{i n} + {χ}_{h {B}_{o u t}} ( x ) {η}_{out} = {χ}_{h {B}_{m}} \frac{{η}_{i n}}{{h}^{2}} + {χ}_{h {B}_{o u t}} \frac{{η}_{o u t}}{{h}^{2}}$$

$$β ( x ) = {χ}_{h {B}_{out}} \frac{{β}_{0}}{{h}^{2}}$$

for constant η₀ and β₀.

### Problem Statement

We want to design a two-layered spherical scatterer (inner and outer layers) with zero scattering. The inner layer is linear (βᵢₙ=0), and the outer layer exhibits the Kerr effect (βₒᵤₜ≠0). We need to determine the susceptibility coefficients (ηᵢₙ and ηₒᵤₜ) and the Kerr coefficient (βₒᵤₜ) to achieve zero scattering.

In the limit of small scatterers, the field u₀(x) is often assumed to be uniform within each layer due to the quasi-static approximation. This approximation holds when the scatterer size is much smaller than the wavelength, allowing the field to be approximated as spatially constant inside the scatterer (Jackson, 1999) (Ammari et al., 2018).

Mathematically, if h is the small parameter defining the scatterer size, then for a function u(x), we expand:

$$u ( x ) = {u}_{0} + O ( h ) ,$$

where the first-order term O(h) is negligible in the asymptotic limit. This approximation is widely used in resonant small-volume high-contrast media (Moskow, 2015) (Ammari et al., 2018).

Thus, we assume:

$${u}_{0} ( x ) \approx constant within each layer .$$

However, this assumption does not limit the generality of the analysis. The uniformity of u₀(x) is a mathematical simplification that allows us to reduce the problem to tractable forms while maintaining the core physical behavior. The analysis can be extended to account for more complex field distributions and geometries if necessary.

### Step 1: Zero-Scattering Condition

The zero-scattering condition is:

$${\sum }_{k = 1}^{n} {η}^{k} {U}_{k} + {β}^{k} {U}_{k}^{β} = 0$$

For a two-layered system (inner and outer layers), this simplifies to:

$${η}_{i n} {U}_{in} + {η}_{out} {U}_{out} + {β}_{out} {U}_{out}^{β} = 0$$

$${U}_{i n} = {u}_{0} {V}_{i n} , {U}_{o u t} = {u}_{0} {V}_{out} , {U}_{out}^{β} = {u}_{0}^{3} {V}_{out}$$

where:

$${V}_{i n} = \frac{4}{3} π {r}_{i n}^{3}$$

is the volume of the inner layer in the scaled domain B,

$${V}_{out} = \frac{4}{3} π ( {r}_{out}^{3} - {r}_{i n}^{3} )$$

is the volume of the outer layer in the scaled domain B Substituting the field integrals into the zero-scattering condition:

$${η}_{in} {r}_{in}^{3} + ( {η}_{out} + {β}_{out} {\vert {u}_{0} \vert}^{2} ) ( {r}_{out}^{3} - {r}_{i n}^{3} ) = 0 .$$

### Parameters of the Physical Setting

### Given the High-Contrast Configuration:

Inner Layer (Diamond): ηᵢₙ=500.
Outer Layer (Silver at ENZ frequency): ηₒᵤₜ=−5000.
Kerr Coefficient (Outer Layer):

$${β}_{out} = {10}^{- 18} \frac{{m}^{2}}{{V}^{2}}$$

Geometry: Let the inner radius rᵢₙ=1 (scaled domain). We need to solve for the outer radius rout.

### Step 2: Adjusting Scaled Field Intensity

The physical field intensity is chosen based on experimental studies of strong Kerr nonlinearities in nanophotonics. In particular, Indium Tin Oxide (ITO) near its epsilon-near-zero (ENZ) frequency has been shown to exhibit intensities in the range of

$$1 {0}^{16} - 1 {0}^{18} \frac{{V}^{2}}{{m}^{2}} ( Boyd , 2020 )$$

### (Alam et al., 2016).

### Using a Representative Value:

$${\vert u \vert}_{physical}^{2} = 5 \times 1 {0}^{17} \frac{{V}^{2}}{{m}^{2}} .$$

### Applying the Volume Scaling Relationship:

$${\vert {u}_{0} \vert}^{2} = {h}^{3} {\vert u \vert}_{p h y s i ca1}^{2} ,$$

with h=10⁻⁹ (nanoscale), we compute:

$${\vert {u}_{0} \vert}^{2} = {( 1 {0}^{- 9} )}^{3} \times 5 \times 1 {0}^{17} = 5 \times 1 {0}^{- 10} .$$

### Step 3: Solve for Rout

Substituting the high-contrast material parameters:

$$500 \cdot {1}^{3} + ( - 5000 + {β}_{out} {\vert {u}_{0} \vert}^{2} ) ( {r}_{out}^{3} - 1 ) = 0 .$$

Neglecting the nonlinear term βₒᵤₜ|u₀|² (since it is much smaller compared to ηₒᵤₜ):

$$500 + ( - 5000 ) ( {r}_{out}^{3} - 1 ) = 0 .$$

Rearranging:

$$50 \; 00 ( {r}_{out}^{3} - 1 ) = 500 .$$

Solving for rₒᵤₜ:

$${r}_{out}^{3} - 1 = \frac{500}{5000} = 0.1 .$$

$${r}_{out}^{3} = 1.1 .$$

$${r}_{out} = \sqrt[3]{11} \approx 1.03 .$$

### Step 4: Rescaling to Physical Dimensions

Using h=10⁻⁹, the physical dimensions are:

$${r}_{i n , p h y s ical} = h \cdot {r}_{i n} = 1 {0}^{- 9} \times 1 = 1 nm . {r}_{out , physical} = h \cdot {r}_{o u t} = 1 {0}^{- 9} \times 1.03 = 1.03 nm .$$

### Conclusion

By utilizing the specified material properties and geometric dimensions, we have successfully attained zero scattering. This setup is physically relevant for plasmonic resonators and nanophotonics applications.

Engineering Optical Materials with Targeted Refractive Indices

Referring to FIG. 4, designing media with a desired refractive index involves tailoring the material properties (e.g., susceptibility, geometry, and nonlinearity) to achieve a specific effective refractive index n_{eff}. The formula for the effective refractive index presented above is groundbreaking because it allows for the design of a wide range of optical materials and devices with specific functionalities. This capability has implications for applications such as subwavelength imaging, perfect lenses, cloaking devices, and highly efficient antennas and waveguides. This can revolutionize the design of optical devices and systems, leading to advancements in various fields, including telecommunications, medical imaging, and energy transfer. More broadly, the ability to engineer the refractive index will revolutionize photonics, leading to breakthroughs in optical computing, communication, and sensing technologies. To contrast with the previous example involving nonlinear effects, the following example demonstrates the design of a targeted refractive index in linear media.

### Problem Statement

We want to design a two-layered spherical scatterer (inner and outer layers) with a preset effective refractive index n_{eff}=2.0. The materials are linear (no Kerr effect, so β=0), and we need to determine the susceptibility coefficients (ηᵢₙ and ηₒᵤₜ) and the geometry (radii rᵢₙ and rₒᵤₜ) to achieve the desired n_{eff}.

### Step 1: Effective Refractive Index Formula

The effective refractive index n_{eff} for a multilayered system is given by:

$${η}_{eff} = \sqrt{1 + {η}_{eff}}$$

where the effective susceptibility η_{eff} is:

$${η}_{eff} = \frac{{\sum }_{k = 1}^{n} {η}^{k} {U}_{k}}{{U}_{0}}$$

For a two-layered system (inner and outer layers), this simplifies to:

$${η}_{eff} = \frac{{η}_{i n} {U}_{i n} + {η}_{out} {U}_{out}}{{U}_{0}}$$

### Step 2: Field Distribution Assumption

For small scatterers, we assume that the field u₀(x) is approximately uniform within each layer, as discussed in greater detail in Example 1. Thus:

$${U}_{i n} = {u}_{0} {V}_{i n} , {U}_{o u t} = {u}_{0} {V}_{out} , {U}_{0} = {u}_{0} {V}_{t otal}$$

where:

$${V}_{i n} = \frac{4}{3} π {r}_{i n}^{3}$$

is the volume of the inner layer in the scaled domain B,

$${V}_{out} = \frac{4}{3} π ( {r}_{out}^{3} - {r}_{i n}^{3} )$$

is the volume of the outer layer in the scaled domain B,

$${V}_{total} = \frac{4}{3} π {r}_{out}^{3}$$

is the total volume of the scatterer in the scaled domain B.

### Step 3: Effective Susceptibility Formula

Substituting the field integrals into the effective susceptibility formula:

$${η}_{eff} = \frac{{η}_{i n} {V}_{i n} + {η}_{out} {V}_{o u t}}{{V}_{total}}$$

### Substituting the Volumes:

$${η}_{eff} = \frac{{η}_{in} {r}_{in}^{3} + {η}_{out} ( {r}_{out}^{3} - {r}_{in}^{3} )}{{r}_{out}^{3}}$$

### Step 4: Desired Refractive Index

Suppose we want the effective refractive index to be n_{eff}=2.0. Then:

$${n}_{eff}^{2} = 1 + {η}_{eff} ⇒ {η}_{eff} = {n}_{eff}^{2} - 1 = 4 - 1 = 3$$

Thus, we need:

$$\frac{{η}_{in} {r}_{in}^{3} + {η}_{out} ( {r}_{out}^{3} - {r}_{in}^{3} )}{{r}_{out}^{3}} = 3$$

### Step 5: Material and Geometry Choices

Let's choose realistic materials and geometry:
Inner layer (Core): Silicon (Si) with ηᵢₙ=11.7.
Outer layer (Shell): Glass with ηₒᵤₜ=2.25.
Geometry: Let the inner radius rᵢₙ=1 (scaled domain). We need to solve for the outer radius rₒᵤₜ.

Substitute the values into the effective susceptibility equation:

$$\frac{11.7 \cdot {1}^{3} + 2.25 \cdot ( {r}_{out}^{3} - {1}^{3} )}{{r}_{out}^{3}} = 3$$

Simplify:

$$\frac{11.7 + 2.25 ( {r}_{out}^{3} - 1 )}{{r}_{out}^{3}} = 3$$

Multiply through by

$${r}_{out}^{3} :$$

$$11.7 + 2.25 {r}_{out}^{3} - 2.25 = 3 {r}_{out}^{3}$$

Combine Like Terms:

$$9.45 + 2.25 {r}_{out}^{3} = 3 {r}_{out}^{3}$$

Solve for

$${r}_{out}^{3} :$$

$$9.45 = 0.75 {r}_{out}^{3} ⇒ {r}_{out}^{3} = \frac{9.45}{0.75} = 12.6$$

Thus:

$${r}_{out} = \sqrt[3]{12.6} \approx 2.32$$

### Step 6: Rescaling to Small Volumes

To rescale the scatterer to small volumes, we introduce the scaling factor h. Let h=10⁻⁹ (nanoscale). The physical radii are:

$${r}_{in , physical} = h \cdot {r}_{in} = h \cdot 1 = h , \\ {r}_{out , physical} = h \cdot {r}_{out} \approx h \cdot 2.32 .$$

For h=10⁻⁹

$${r}_{in , physical} = 1 nm , {r}_{out , physical} \approx 2.32 nm .$$

### Conclusion

To achieve an effective refractive index of n_{eff}=2.0, we can design a two-layered spherical scatterer with:
Inner layer: Silicon (Si) with ηᵢₙ=11.7 and radius r_{in,physical}=1 nm,
Outer layer: Glass with ηₒᵤₜ=2.25 and outer radius r_{out,physical}≈2.32 nm.

### Key Advantages

Dual Optimization of Material and Geometry: Unlike homogenization-based methods, the proposed approach co-designs susceptibility coefficients (ηᵢₙ, ηₒᵤₜ) and radii (rᵢₙ, rₒᵤₜ) using the explicit formula:

$${η}_{eff} = \frac{{η}_{in} {r}_{in}^{3} + {η}_{out} ( {r}_{out}^{3} - {r}_{in}^{3} )}{{r}_{out}^{3}} = 3 ,$$

enabling precise control over n_{eff}=2.0.
Linear Material Stability: Avoids nonlinear effects (β=0) common in Kerr-media methods, ensuring intensity-independent performance:

$${n}_{eff} = \sqrt{1 + {η}_{eff}} ( constant for linear materials ) .$$

Nanoscale Fabrication Feasibility: Rescaling to physical radii r_{in,physical}=h·1 and r_{out,physical}≈h·2.32 (for h=10⁻⁹) ensures compatibility with atomic-scale manufacturing.
Analytical Simplicity: Directly solves for rₒᵤₜ without numerical optimization:

$${r}_{out} = \sqrt[3]{12.6} \approx 2.32$$

Comparison of methods to achieve n_{eff}=2.0

TABLE I
Comparison of Methods

| | | Proposed Method's |
|---|---|---|
| Method | Limitations | Advantage |
| Homogenization | Ignores geometric | Explicit η-r co-design |
| Theory | parameters | |
| Nonlinear Media | Intensity-dependent | Linear (β = 0), stable |
| (β ≠ 0) | instability | |
| Multi-layer Stacks | Complex fabrication | Two-layer simplicity |

The method's closed-form solution for a two-layered scatterer with silicon (ηᵢₙ=11.7) and glass (ηₒᵤₜ=2.25) achieves n_{eff}=2.0 at the nanoscale, outperforming existing approaches in stability, scalability, and practicality for photonic devices.

Effective Negative Refractive Index Under Quasi-Static Approximation with Physical Application

The negative refractive index serves as a foundational principle for revolutionary photonic technologies, enabling breakthroughs such as electromagnetic cloaking, superlensing, and subwavelength imaging. Its unique properties have been rigorously exploited to advance applications in optical invisibility, ultra-high-resolution microscopy, and next-generation metamaterial-based devices.

We aim to design a three-layered spherical scatterer such that the effective refractive index n_{eff} of the entire structure is negative. This property was derived under the quasi-static approximation.

### Clarification on Negative Refractive Index

The standard equation for the effective refractive index is:

$${n}_{eff}^{2} = 1 + {η}_{eff}$$

which does not distinguish between n_{eff}=−1.5 and n_{eff}=1.5. To explicitly enforce negative refraction, we introduce the sign function:

$${n}_{eff} = sgn ( {μ}_{eff} ) \sqrt{1 + {η}_{eff}} .$$

where μ_{eff} is the effective permeability of the layered structure. Negative refraction occurs when:
The inner layer (gold) exhibits strong plasmonic response.
The middle layer (ITO) operates near its epsilon-near-zero (ENZ) frequency, causing μ_{eff}<0.
The nonlinear Kerr effect in ITO enhances dispersion, reinforcing μ_{eff}<0.

Since μ_{eff}<0 in this configuration, we enforce:

$${n}_{eff} = - \sqrt{1 + {η}_{eff}} = - 1.5 .$$

Thus, this material exhibits true negative refraction, distinguishing it from a standard positive index material (Pendry 2000).

### Problem Statement

Given a three-layered spherical scatterer (inner, middle, and outer layers), we want to achieve an effective refractive index n_{eff}=−1.5. To do so, we will determine:
The susceptibility coefficients (ηᵢₙ, η_{mid}, ηₒᵤₜ).
The Kerr coefficient (β_{mid}) for the nonlinear middle layer.
The geometry (radii rᵢₙ, r_{mid}, rₒᵤₜ).
We assume h=10⁻⁹ for scaling, and |u₀|²=5×10⁻¹⁰, as previously derived.

### Step 1: Effective Susceptibility and Refractive Index

From the effective medium theory formula:

$${η}_{eff} = \frac{{\sum }_{k = 1}^{3} ( {η}^{k} {U}_{k} + {β}^{k} {U}_{k}^{β} )}{{U}_{0}} .$$

The corrected formula for the effective refractive index is:

$${n}_{eff} = sgn ( {μ}_{eff} ) \sqrt{1 + {η}_{eff}} .$$

For n_{eff}=−1.5, we calculate:

$$1.25 = {η}_{eff} = \frac{{η}_{in} {r}_{in}^{3} + {η}_{mid} ( {r}_{mid}^{3} - {r}_{in}^{3} ) + {η}_{out} ( {r}_{out}^{3} - {r}_{mid}^{3} )}{{r}_{out}^{3}} .$$

Step 2: Solving for rₘid and rₒᵤₜ
Inner Layer (Gold): ηᵢₙ=−100.
Middle Layer (ITO): η_{mid}=10, β_{mid}=10⁻¹⁰ m²/V².
Outer Layer (Silicon): ηₒᵤₜ=11.7.

Setting rᵢₙ=1, we substitute into the susceptibility equation:

$$1.25 {r}_{out}^{3} = - 100 + 10 ( {r}_{mid}^{3} - 1 ) + 11.7 ( {r}_{out}^{3} - {r}_{mid}^{3} ) .$$

### Rearrange:

$$1.25 {r}_{out}^{3} - 11.7 {r}_{out}^{3} = - 100 + 10 {r}_{mid}^{3} - 10 - 11.7 {r}_{mid}^{3} .$$

Solving numerically with r_{mid}=1.5:

$${r}_{out}^{3} = \frac{- 110 - 1.7 ( {1.5}^{3} )}{- 10.45} \approx 11.07 .$$

Thus:

$${r}_{out} \approx \sqrt[3]{11.07} \approx 2.23 .$$

### Step 3: Physical Application—Cloaking Device

The configuration described here can be used as a cloaking device, minimizing scattering and redirecting electromagnetic waves around an object. The use of a negative-index material enables invisibility effects, useful in stealth applications, optical sensing, and wave manipulation in the infrared and visible spectra.

### Example 3

Scattering resonances play a crucial role in understanding wave behavior in various physical systems. While significant progress has been made in analyzing resonances in high-contrast and nonlinear media, a general characterization of resonances in small, high-contrast nonlinear media with the Kerr effect, particularly in layered configurations, has remained an open problem. EXAMPLE 3 demonstrates an asymptotic approach that addresses this gap by providing an approximation for resonances in terms of material properties, geometry, and nonlinearity. Our results offer new insights into the dependence of resonances on these factors, particularly for complex multilayered structures, making this the first general characterization of its kind. The formulas presented in this work lay a new theoretical foundation for the study of high-contrast, nanoscale resonances and nonlinear effects in layered media. Given their broad applicability across nanophotonics and advanced materials science, these results have the potential to become pivotal in shaping future developments in the field, analogous to the role of fundamental equations in other scientific domains.

The study of scattering resonances in high-contrast media has attracted considerable attention due to its broad implications across various scientific and technological disciplines. These resonances, originating from the interaction of waves with material interfaces and inhomogeneities, underpin a wide range of phenomena, including light trapping in solar cells (Zhou & Biswas, 2010), sound absorption in acoustic metamaterials (Cummer et al., 2016), and the manipulation of electromagnetic waves in advanced communication systems (Alu & Engheta, 2007).

The engineering of exotic structures with complex geometries and customized optical properties has indeed seen remarkable growth, driven by advances in materials science and nanotechnology. Pendry's work (Pendry 2000) on negative index materials was a groundbreaking contribution to this field.

These structures enable unprecedented control over electromagnetic waves, allowing for phenomena that aren't possible with conventional materials. The ability to manipulate light at the nanoscale has opened up possibilities for applications like super-resolution imaging, optical cloaking, and highly efficient photonic devices.

However, analyzing wave propagation and resonance behavior in such complex systems often demands computationally intensive numerical simulations. Asymptotic methods, which offer approximate solutions in specific regimes, present a powerful alternative for gaining insights into these phenomena without relying on extensive numerical computations. EXAMPLE 3 demonstrates the development of an asymptotic approach to characterize scattering resonances in small, high-contrast nonlinear optical multilayered media exhibiting the Kerr effect. This nonlinearity, where the scattering resonances depend on both the refractive index and the intensity of the incident light, introduces an additional layer of complexity to the problem. One objective is to derive an approximation for the resonances that illuminates their dependence on material properties, geometry, and the strength of the nonlinearity, particularly in the context of layered structures.

Prior research has explored resonances in high-contrast media using a variety of techniques. The first rigorous quantification of these resonances, in both linear and nonlinear regimes, was presented in (Meklachi et al., 2018), where a scaling approach and Lippmann-Schwinger integral solution to the Helmholtz equation were employed for a single volume. Additionally, (Ammari et al., 2018) established a mathematical framework for analyzing resonances in subwavelength resonator structures, primarily focusing on the linear regime. The influence of nonlinearity on resonance behavior has been investigated in several studies. For example, Moskow (Moskow, 2015) examined nonlinear eigenvalue approximation for compact operators, providing a theoretical foundation for analyzing resonances in nonlinear systems. The work by Ammari et al. (Ammari et al., 2022) further extended these concepts to the context of high-contrast plasmonic media, employing layer potential techniques to approximate resonances.

Moreover, the study of resonances in nonlinear optical media has been a subject of active research. The Kerr effect has been extensively investigated due to its role in phenomena like self-focusing, soliton formation, and optical bistability (Boyd, 2020). Theoretical and numerical studies have explored the impact of the Kerr nonlinearity on resonance frequencies and mode profiles in various configurations (Poutrina et al., 2010; Suchkov et al., 2000).

While these previous works have significantly advanced our understanding of resonances in high-contrast and nonlinear media, a general characterization of resonances in small, high-contrast nonlinear media with Kerr effect, especially in layered configurations, remains an open problem. Our work aims to bridge this gap by providing an asymptotic approximation that encapsulates the essential physics of the problem. We build upon the foundations laid by previous research, extending them to incorporate the nonlinear Kerr effect and providing a more comprehensive understanding of resonance phenomena in these complex systems.

The potential applications of our research are vast and diverse. In the domain of photonics, our findings could facilitate the design of novel metamaterials with exotic optical properties, enabling advancements in optical sensing, light manipulation, and energy harvesting (Soukoulis & Wegener, 2011). In the realm of acoustics, the ability to precisely control resonances in small structures could lead to the development of acoustic metamaterials with superior sound control capabilities, impacting noise reduction and architectural acoustics (Ma et al., 2014). Furthermore, our work could have ramifications for medical imaging (Dabrowski et al., 2020), where resonant nanoparticles could function as contrast agents or enable targeted drug delivery (Kircher et al., 2014). In electronics and telecommunications, a deeper understanding of resonances could lead to the design of smaller, more efficient antennas and improved electromagnetic shielding (Alitalo & Koppens, 2015). Finally, our research could contribute to the development of more efficient energy harvesting and conversion devices, such as solar cells and thermoelectric devices (Atwater & Polman, 2010).

EXAMPLE 3 expands upon the results in (Meklachi et al., 2018).

Effective Resonances in Small, Multilayered, High-Contrast, Nonlinear Scatterers with Arbitrary Geometry

### The Original Work

Again we expand upon the results in (Meklachi et al., 2018).

Consider a small volume high contrast nonlinear medium exhibiting Kerr effect of arbitrary geometry. The governing Helmholtz equation:

$$Δ u + {k}^{2} ( 1 + η ( x ) ) u + {k}^{2} β ( x ) {\vert u \vert}^{2} u = 0 ,$$

subject to Sommerfeld radiation condition at infinity, builds on classical scattering theory (Jackson, 1999), extended here to incorporate nonlinear Kerr effects in layered geometries.

k is the wave number, η is the medium susceptibility coefficient, and u is the scalar field. Here, λ=k² is the spectral parameter.

Lippmann-Schwinger Integral solution translate to the integral eigenvalue problem that is nonlinear in both λ and u:

$$λ T ( λ ) u = u$$

$$Where$$

$$T ( λ ) ( u ) ( x ) = \frac{1}{4 π} {\int }_{hB} η ( y ) \frac{exp ( i \sqrt{λ} \vert x - y \vert )}{\vert x - y \vert} u ( y ) dy + \frac{1}{4 π} {\int }_{hB} β ( y ) \frac{exp ( i \sqrt{λ} \vert x - y \vert )}{\vert x - y \vert} {\vert u ( y ) \vert}^{2} u ( y ) dy$$

By scaling the spatial variables and the media properties as follows:

$$η = {χ}_{hB} \frac{{η}_{0}}{{h}^{2}} , β = {χ}_{hB} \frac{{β}_{0}}{{h}^{2}} , x = h \tilde{x} , y = h \tilde{y}$$

we obtain:

$${λ}_{h} {T}_{h} ( {λ}_{h} ) {u}_{h} = {u}_{h}$$

$$where$$

$${T}_{h} ( λ ) ( u ) ( \tilde{x} ) = \frac{1}{4 π} {\int }_{B} {η}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) d \tilde{y} + \frac{1}{4 π} {\int }_{B} {β}_{0} ( h \tilde{y} ) \frac{exp ( i \sqrt{λ} h \vert \tilde{x} - \tilde{y} \vert )}{\vert \tilde{x} - \tilde{y} \vert} u ( \tilde{y} ) {\vert u ( \tilde{y} ) \vert}^{2} u ( y ) d \tilde{y}$$

The associated limiting eigenvalue problem, as h→0 is:

$${λ}_{0} {T}_{0} ( {λ}_{0} ) {u}_{0} = {u}_{0} ,$$

$$where$$

$${T}_{0} ( u ) ( \tilde{x} ) = \frac{1}{4 π} {\int }_{B} {η}_{0} ( 0 ) \frac{u ( \tilde{y} )}{\vert \tilde{x} - \tilde{y} \vert} d \tilde{y} + \frac{1}{4 π} {\int }_{B} {β}_{0} ( 0 ) \frac{u ( \tilde{y} )}{\vert \tilde{x} - \tilde{y} \vert} {\vert u ( \tilde{y} ) \vert}^{2} d \tilde{y}$$

Now that Tₕ and T₀ are well defined, we can compute the asymptotic formula by executing the inner product in the formula:

$${λ}_{h} = {λ}_{0} + {λ}_{0}^{2} 〈 ( {T}_{0} - {T}_{h} ( {λ}_{0} ) ) {u}_{0} , {u}_{0} 〉 + 𝒪 ( {h}^{2} )$$

Generalized Framework for Linear and Nonlinear Multilayered High-Contrast Scatterers with Arbitrary Geometry

Suppose Bₕ is composite and optically inhomogenous with n layers of concentric high contrast media {Bᵢ}_{1≤i≤n}, such that:

$$hB = {⋃}_{i = 1}^{i = n} h {B}_{i} ,$$

$$η ( x ) = {\sum }_{i = 1}^{i = n} {χ}_{h {B}_{i}} ( x ) {η}^{i} = {\sum }_{i = 1}^{i = n} {χ}_{h {B}_{i}} ( x ) \frac{{η}_{0}^{i}}{{h}^{2}} ,$$

$$β ( x ) = {\sum }_{i = 1}^{i = n} {χ}_{h {B}_{i}} ( x ) {β}^{i} = {\sum }_{i = 1}^{i = n} {χ}_{h {B}_{i}} ( x ) \frac{{β}_{0}^{i}}{{h}^{2}} ,$$

$${η}_{0} ( x ) = {\sum }_{i = 1}^{i = n} {χ}_{{B}_{i}} ( x ) {η}_{0}^{i} , {β}_{0} ( x ) = {\sum }_{i = 1}^{i = n} {χ}_{{B}_{i}} ( x ) {β}_{0}^{i}$$

Similar to the previous cases, the operators Tₕ and T₀ write:

$${T}_{h} ( u ) ( x ) ( λ ) = {\sum }_{k = 1}^{k = n} \frac{{η}_{0}^{k}}{4 π} {\int }_{{B}_{k}} \frac{exp ( i \sqrt{λ} h \vert x - y \vert )}{\vert x - y \vert} u ( y ) dy + \frac{{β}_{0}^{k}}{4 π} {\int }_{{B}_{k}} \frac{exp ( i \sqrt{λ} h \vert x - y \vert )}{\vert x - y \vert} u ( y ) {\vert u ( y ) \vert}^{2} dy$$

$${T}_{0} ( u ) ( x ) = {\sum }_{k = 1}^{k = n} \frac{{η}_{0}^{k}}{4 π} {\int }_{{B}_{k}} \frac{1}{\vert x - y \vert} u ( y ) d y + \frac{{β}_{0}^{k}}{4 π} {\int }_{{B}_{k}} \frac{1}{\vert x - y \vert} u ( y ) {\vert u ( y ) \vert}^{2} d y$$

We perform a Taylor expansion of h→exp(i\sqrt{λ}h|x−y|) again, yielding:

$${T}_{h} ( λ ) ( u ) ( x ) = {T}_{0} ( λ ) ( u ) ( x ) + \frac{i \sqrt{λ} h}{4 π} ( {\sum }_{k = 1}^{n} {η}_{0}^{k} {\int }_{{B}_{k}} u ( y ) dy + {β}_{0}^{k} {\int }_{{B}_{k}} u ( y ) {\vert u ( y ) \vert}^{2} d y + ) + 𝒪 ( {h}^{2} )$$

We can now evaluate (1) at u₀ and λ₀, which gives:

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} )$$

$$where {U}_{0} = {\int }_{B} {u}_{0} ( x ) d x , {U}_{k} = {\int }_{{B}_{k}} {u}_{0} ( x ) dx , and$$

$${U}_{k}^{β} = {\int }_{{B}_{k}} {u}_{0}^{3} ( x ) d x , 1 \leq k \leq n .$$

The expression encapsulates the spectral characteristics, specifically the resonance properties, of the multilayered medium in its entirety.

In linear media, in the absence of Kerr effect for example, the formula simply writes:

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} ] h + 𝒪 ( {h}^{2} )$$

which is very useful in the analysis of resonances of composite complex layered high contrast media. The formula provides a wide range of possibilities for the design of many novel configurations, where for a multilayered material, if one layer is desired to be linear, its corresponding Kerr coefficient, βₖ, can be set to zero. The formula can be used as a predictor on how the changes in the parameters of the media would affect the resonances. There is a plethora of applications of this formula. These methods can be applied in two complementary ways:
1. Resonance Property Calculation: Determining the resonance characteristics of a complex, small inclusion based on its material and geometric properties.
2. Intrinsic Property Detection: Inferring the intrinsic properties of the inclusion from a measured or desired resonance shift, Δλ=λₕ−λ₀.

The formulas provide the first general asymptotic approximation for scattering resonances in multilayered, high-contrast nonlinear media with the Kerr effect. Aspects of the formulas can provide:
Multilayer integration: Explicitly accounts for interactions between multiple layers with distinct linear (η₀^{k}) and nonlinear (β₀^{k}) coefficients.
Nonlinearity in layered media: Incorporates the Kerr effect (β₀^{k} terms) for each layer, enabling analysis of intensity-dependent resonances in complex geometries.
Generalized framework: Unifies linear and nonlinear contributions into a single predictive formula, resolving an open problem in the field.
Scaling and operator formulation: Extends the Lippmann-Schwinger framework to nonlinear eigenvalue problems with multiple layers. Introduces scaled operators Tₕ (λ) and T₀ to handle geometry-dependent nonlinearities.
Asymptotic expansion: Requires a non-trivial Taylor expansion to separate linear and nonlinear terms across layers. Balances the interplay between layer-specific integrals Uk, and nonlinear contributions Uk β

Applications can include:
Design of nonlinear metamaterials: Predict resonance shifts in layered structures with tailored ηk, βk, and geometry for applications in optical computing, sensing, and energy harvesting.
Nanophotonic devices: Optimize multilayered resonators (e.g., photonic crystals, plasmonic nanoparticles) for nonlinear effects like soliton generation or optical bistability.
Inverse problem solving: Infer material properties (ηk, βk) from measured resonance shifts (Δλ), enabling non-destructive testing of nanostructures.

While asymptotic techniques exist, their application to multilayered nonlinear systems with coupled linear/nonlinear terms is unprecedented. The formulae uniquely address the open problem of small-volume, high-contrast layered media.

### Example Use Case

A photonics engineer can use the formulae to design a nonlinear metasurface with alternating TiO₂ (high η) and ITO (high β) layers, predicting resonance wavelengths for desired optical switching behavior without computationally intensive simulations.

### Example 4

### Introduction

This EXAMPLE introduces a three-layered nanoparticle (core-middle-shell) designed as a contrast agent for fluorescence imaging in biological tissues, operating within a medium of refractive index nₘ=1.33. By inducing a controlled imaginary resonance shift Δλ=−i 1.0×10¹² m⁻² from an 800 nm base resonance, this nanoparticle enhances optical absorption, significantly boosting energy transfer to near-infrared (NIR) fluorophores and amplifying fluorescence emission for deep-tissue imaging, such as tumor visualization. The primary contribution lies in its multilayered architecture—combining plasmonic gold (Chen et al., 2013), nonlinear indium tin oxide (ITO), and dielectric silicon—to precisely tune absorption while preserving non-zero scattering contrast, a synergy not fully exploited in prior art.

Compared to conventional fluorescence imaging methods, this design offers distinct advantages. Traditional contrast agents, such as single-material gold nanorods, rely on fixed plasmonic resonances (Maier, 2007) that often detune in varying tissue environments, reducing efficiency (Kircher 2014). Organic dyes, while widely used, suffer from photobleaching and limited penetration depth (Ntziachristos 2010). Quantum dots provide high brightness but pose toxicity concerns (Walling 2009). In contrast, our nanoparticle leverages the nonlinear Kerr effect of ITO to dynamically enhance absorption at 800 nm, a wavelength optimal for tissue penetration (Diekmann 2020), while the gold core ensures robust plasmonic enhancement and the silicon shell stabilizes the structure. This approach outperforms scattering-focused designs (Alu 2007) by prioritizing absorption over cloaking, and it advances multilayered plasmonic strategies (Poutrina 2010) by integrating medium-specific tuning for fluorescence applications. The result is a safer, more effective imaging tool with potential to revolutionize deep-tissue diagnostics. Specifically, this absorption-enhanced fluorescence technique can be employed for in vivo imaging and detection of deep-seated tumors, significantly enhancing spatial resolution and contrast compared to traditional methods (Weissleder, 2001).

We aim to solve for the scaled material properties

$$( {η}_{0}^{k} , {β}_{0}^{k} )$$

of all layers, specifically determining β₀² for the middle ITO layer, to achieve an exact imaginary resonance shift Δλ=−i·1.0×10¹² m⁻² from the medium-adjusted base resonance

$${λ}_{0}^{m e d} = 1.0909 \times 1 {0}^{14} {m}^{- 2}$$

(corresponding to 800 nm in a biological medium with nₘ=1.33). This increases absorption at 800 nm in tissue, enhancing fluorescence signals while ensuring scattering contrast.

### Methodology

### Resonance Condition in Medium

The resonance shift formulation builds on classical electrodynamic principles (Jackson, 1999) and per turbative analysis of plasrmonic systems (Ammari et al, 2018). In the limit where the scatterer is much smaller than the wavelength, consider a uniform field u₀, which simplifies the resonance formula:

$${λ}_{h} = {λ}_{0} - i \frac{{λ}_{0}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} )$$

for k=3 to:

$${λ}_{h}^{m e d} = {λ}_{0}^{m e d} - i \frac{{( {λ}_{0}^{m e d} )}^{5 / 2}}{4 π} {u}_{0} V [ {\sum }_{k = 1}^{3} {u}_{0} {V}_{k} ( \frac{{η}_{0}^{k}}{{n}_{m}^{2}} + {β}_{0}^{k} {u}_{0}^{2} ) ] h + O ( {h}^{2} )$$

where:

$${λ}_{h}^{med} :$$

shifted resonance (m⁻²)

$${λ}_{0}^{m e d} :$$

base resonance in medium (m⁻²),
nₘ=1.33: medium refractive index (ϵₘ=1.77),
u₀: uniform field intensity (V/m),
V: total scaled volume,

$${η}_{0}^{k} :$$

scaled linear susceptibility (vacuum-defined, m⁻²),
Vₖ: scaled volume of layer k,

$${β}_{0}^{k} :$$

scaled Kerr coefficient (m²/V²)
h: scaling parameter (m),
n=3: number of layers.

Physical properties:

$${η}_{physical}^{k} = {η}_{0}^{k} {h}^{2} , {β}_{physical}^{k} = {β}_{0}^{k} {h}^{2} .$$

Target shift: Δλ=−i·1.0×10¹² m⁻².

### Design Parameters

Structure: Three concentric spherical layers:
a. Core: Gold (plasmonic, linear,

$${β}_{0}^{1} = 0 ) ,$$

b. Middle: Indium Tin Oxide (ITO, nonlinear Kerr effect),
c. Shell: Silicon (dielectric, linear,

$${β}_{0}^{3} = 0 ) .$$

Scaling Parameter: h=10⁻⁹ m.
Physical Radii: r₁=10 nm, r₂=20 nm, r₃=30 nm.
Scaled Radii: r₁ₛ=10, r₂ₛ=20, r₃ₛ=30.
Laser Intensity: u₀=10⁵ V/m (safe for imaging, (Diekmann 2020)).
Base Resonance in Medium:

$${λ}_{0}^{v a c} = {( \frac{2 π}{800 \times 1 {0}^{- 9}} )}^{2} \approx 6.1685 \times 1 {0}^{13} {m}^{- 2}$$

$${λ}_{0}^{m e d} = {n}_{m}^{2} \cdot {λ}_{0}^{v a c} = 1 \text{.7689} \cdot 6.1685 \times 1 {0}^{13} \approx 1.0909 \times 1 {0}^{14} {m}^{- 2}$$

Target Shift: Δλ=−i·1.0×10¹² m⁻²,
Shifted Resonance:

$${λ}_{h}^{m e d} = 1.0909 \times 1 {0}^{14} - i \cdot 1. \times 1 {0}^{12} {m}^{- 2} .$$

Scaled Volumes

$$Layer 1 : {V}_{1} = \frac{4}{3} {π ( 10 )}^{3} \approx 4188.79 ,$$

$$Layer 2 : {V}_{2} = \frac{4}{3} π ( 2 {0}^{3} - 1 {0}^{3} ) \approx 29321.53 ,$$

$$Layer 3 : {V}_{3} = \frac{4}{3} π ( 3 {0}^{3} - 2 {0}^{3} ) \approx 79586.61 ,$$

$$Total Scaled Volume : V = \frac{4}{3} {π ( 30 )}^{3} \approx 113097.34 .$$

### Solving for Material Properties

### Substitute the Target Shift:

$$Δ λ = - i \frac{{( {λ}_{0}^{m e d} )}^{5 / 2}}{4 π} {u}_{0} V [ {\sum }_{k = 1}^{3} {u}_{0} {V}_{k} ( \frac{{η}_{0}^{k}}{{n}_{m}^{2}} + {β}_{0}^{k} {u}_{0}^{2} ) ] h$$

$$1. \times 1 {0}^{12} = \frac{{( {λ}_{0}^{m e d} )}^{5 / 2}}{4 π} {u}_{0} V [ {\sum }_{k = 1}^{3} {u}_{0} {V}_{k} ( \frac{{η}_{0}^{k}}{{n}_{m}^{2}} + {β}_{0}^{k} {u}_{0}^{2} ) ] h$$

Calculate:

$${( {λ}_{0}^{m e d} )}^{5 / 2} = {( 1.0909 \times 1 {0}^{14} )}^{5 / 2} \approx 3.9849 \times 1 {0}^{34} {m}^{- 5}$$

$$\frac{{( {λ}_{0}^{m e d} )}^{5 / 2}}{4 π} \approx 3.1710 \times 1 {0}^{33} {m}^{- 5}$$

$${u}_{0} V = 1 {0}^{5} \cdot 113097. 34 = 1.1309734 \times 1 {0}^{10} V$$

$$\frac{{( {λ}_{0}^{m e d} )}^{5 / 2}}{4 π} {u}_{0} V h = 3.1710 \times 1 {0}^{33} \cdot 1.1309734 \times 1 {0}^{10} \cdot {10}^{- 9} = 3.5858 \times 1 {0}^{34}$$

$${\sum }_{k = 1}^{3} {u}_{0} {V}_{k} ( \frac{{η}_{0}^{k}}{{n}_{m}^{2}} + {β}_{0}^{k} {u}_{0}^{2} ) = \frac{1.0 \times 1 {0}^{12}}{3.5858 \times 1 {0}^{34}} \approx 2.7888 \times 1 {0}^{- 23}$$

Since

$${β}_{0}^{1} = 0 and {β}_{0}^{3} = 0 :$$

$${u}_{0} {V}_{1} ( \frac{{η}_{0}^{1}}{{n}_{m}^{2}} ) + {u}_{0} {V}_{2} ( \frac{{η}_{0}^{2}}{{n}_{m}^{2}} + {β}_{0}^{k} {u}_{0}^{2} ) + {u}_{0} {V}_{3} ( \frac{{η}_{0}^{3}}{{n}_{m}^{2}} ) = 2.7888 \times 1 {0}^{- 23}$$

Susceptibilities adjusted for the medium:

$$Layer 1 ( Gold ) : {η}_{physical}^{1} = - 26.77 ( {ϵ}_{g} \approx - 25 ( Chen et al . , 2013 ) , {ϵ}_{m} = 1.77 ) ,$$

$${η}_{0}^{1} = \frac{- 26.77}{{h}^{2}} = - 2.677 \times {10}^{19} {m}^{- 2}$$

$$Layer 2 ( ITO ) : {η}_{physical}^{2} = 0 ( ENZ , ( Alam 2016 ) ) ,$$

$${η}_{0}^{2} = 0$$

$$Layer 3 ( Silicon ) : {η}_{physical}^{3} = 7.84 ( {ϵ}_{Si} \approx 13.87 , {ϵ}_{m} = 1.77 ) ,$$

$${η}_{0}^{3} = \frac{7.84}{{h}^{2}} = 7.84 \times {10}^{18} {m}^{- 2}$$

$${η}_{m}^{2} = 1.7689 , {u}_{0} = 1 {0}^{5}$$

### Resonance Condition in Medium

The silicon shell's dielectric constant ensures structural stability and minimal absorption losses (Maier, 2007).

Substitute:

$${10}^{5} \cdot 4188.79 ( \frac{- 2.677 \times {10}^{19}}{1.7689} ) + {10}^{5} \cdot 29321.53 ( {β}_{0}^{2} \cdot {10}^{10} ) + {10}^{5} \cdot 79586.61 ( \frac{7.84 \times {10}^{18}}{1.7689} ) = 2.7887 \times {10}^{- 23}$$

Calculate:

$${u}_{0} {V}_{1} \frac{{η}_{0}^{1}}{{η}_{m}^{2}} = {10}^{5} \cdot 4188.79 \cdot \frac{- 2.677 \times {10}^{19}}{1.7689} \approx - 6.34 \times {10}^{27} ,$$

$${u}_{0} {V}_{2} {β}_{0}^{2} {u}_{0}^{2} = 1 {0}^{5} \cdot 29321.53 \cdot {β}_{0}^{2} \cdot {10}^{10} = 2.932153 \times 1 {0}^{19} \cdot {β}_{0}^{2} ,$$

$${u}_{0} {V}_{3} \frac{{η}_{0}^{3}}{{n}_{m}^{2}} = 1 {0}^{5} \cdot 79586.61 \cdot \frac{7.84 \times 1 {0}^{18}}{1.7689} \approx 3.5331 \times 1 {0}^{28} \cdot - 6.34 \times 1 {0}^{27} + ( 2.932153 \times 1 {0}^{19} \cdot {β}_{0}^{2} ) + 3.5331 \times 1 {0}^{28} = 2.7888 \times 1 {0}^{- 23}$$

$$2.932153 \times 1 {0}^{19} \cdot {β}_{0}^{2} = 2.7888 \times 1 {0}^{- 23} + 6.3400 \times 1 {0}^{27} - 3.5331 \times 1 {0}^{28} \approx - 2.8991 \times 1 {0}^{28}$$

$${β}_{0}^{2} = \frac{- 2.8991 \times 1 {0}^{28}}{2.932153 \times 1 {0}^{19}} \approx - 9.8873 \times 1 {0}^{8} {m}^{2} / {V}^{2}$$

$${β}_{physical}^{2} = - 9.8873 \times 1 {0}^{8} \cdot {( {10}^{- 9} )}^{2} = - 9.8873 \times 1 {0}^{- 10} {m}^{2} / {V}^{2}$$

### Verification

To confirm the target shift Δλ=−i·1.0×10¹² m⁻², substitute into the resonance equation:

$$Δ λ = - i \frac{{( {λ}_{0}^{m e d} )}^{5 / 2}}{4 π} {u}_{0} V [ {\sum }_{k = 1}^{3} {u}_{0} {V}_{k} ( \frac{{η}_{0}^{k}}{{n}_{m}^{2}} + {β}_{0}^{k} {u}_{0}^{2} ) ] h$$

Calculate the sum:

$$Layer 1 :$$

$$1 {0}^{5} \cdot 4188.79 \cdot \frac{- 2.677 \times 1 {0}^{19}}{1.7689} \approx - 6.3400 \times 1 {0}^{27}$$

$$Layer 2 :$$

$$1 {0}^{5} \cdot 29321.53 \cdot ( - 9.8873 \times 1 {0}^{8} ) \cdot {10}^{10} \approx - 2.8991 \times 1 {0}^{28}$$

$$Layer 3 :$$

$${10}^{5} \cdot 79586.61 \cdot \frac{7.84 \times 1 {0}^{18}}{1.7689} \approx 3.5331 \times 1 {0}^{28} - 6.34 \times 1 {0}^{27} - 2.8991 \times 1 {0}^{28} + 3.5331 \times 1 {0}^{28} \approx 2.7888 \times 1 {0}^{- 23}$$

Prefactor:

$$\frac{{( 1.0909 \times {10}^{14} )}^{5 / 2}}{4 π} \approx 3.171 \times {10}^{33} , \\ 3.171 \times {10}^{33} \cdot 1.1309734 \times {10}^{10} \cdot {10}^{- 9} \approx 3.5858 \times {10}^{34}$$

$$Δλ = - i \cdot 3.5858 \times {10}^{34} \cdot 2.7888 \times {10}^{- 23} \approx - i \cdot 1. \times {10}^{12} {m}^{- 2}$$

This matches the target, verifying the solution.

The use of a three-layered nanoparticle (Gold-ITO-Si) with a controlled imaginary resonance shift Δλ=−i·1.0×10¹² m⁻² at 800 nm, achieved by precisely tuning the middle ITO layer's Kerr coefficient (β₀²), is a unique approach. Unlike traditional contrast agents that rely on fixed plasmonic resonances (Kircher 2014) or broad absorption tuning (Boyd 2020), this method leverages multilayered nonlinear optics to enhance energy transfer to fluorophores in a medium-specific manner (nₘ=1.33). No prior art combines this exact configuration with a targeted imaginary shift for fluorescence amplification.

The nanoparticle significantly improves fluorescence imaging in deep tissue by increasing absorption at 800 nm, boosting signal intensity from NIR dyes while maintaining low laser intensity (u₀=10⁵ V/m) (Diekmann 2020). This enhances tumor visualization sensitivity and specificity, addressing a critical need in oncology diagnostics. Its adaptability to various fluorophores and tissue depths adds practical value for clinical applications.

Achieving a precise imaginary shift through multilayer tuning—balancing plasmonic (gold), nonlinear (ITO), and dielectric (Si) properties—requires a sophisticated integration of optical physics beyond routine optimization. While prior work on effective resonance (Meklachi et al., 2018) primarily addressed single-layer systems, our innovation can translate resonance shift mechanisms to fluorescence enhancement in biological media via a tailored multilayer architecture. This strategy uniquely leverages material synergies across gold, ITO, and silicon layers—enabling nonlinear absorption tuning at 800 nm in tissue—and diverges from scattering-dominated paradigms (Alu, 2007) or generic plasmonic platforms (Poutrina et at, 2010).

The design leverages existing materials (gold nanorods, ITO, silicon) already in use clinically (Kircher 2014), enhancing their efficacy without complex fabrication. It could be integrated into fluorescence imaging systems, a growing market projected to reach billions by 2030, offering a competitive edge in precision diagnostics. Licensing to medical device firms or fluorophore developers is a viable path to commercialization.

This combination of a unique multilayered design, practical imaging benefits, and market readiness positions the nanoparticle as a patent-worthy innovation in biomedical imaging.

### Conclusion

This Gold-ITO-Si nanoparticle with radii r₁=10 nm, r₂=20 nm, r₃=30 nm, and properties

$${η}_{physical}^{1} = - 26.77 , {η}_{physical}^{2} = 0 , \\ {β}_{physical}^{2} = - 9.8873 \times {10}^{- 10} {m}^{2} / {V}^{2} , {η}_{physical}^{3} = 7.84$$

achieves

$$Δλ = - i \cdot 1. \times {10}^{12} {m}^{- 2} at {λ}_{0}^{med} = 1.0909 \times {10}^{14} {m}^{- 2} in a medium ( {n}_{m} = 1.33 ) ,$$

enhancing fluorescence imaging.

### Example 5

Plasmonic photothermal therapy (PPTT) is a promising technique that utilizes gold nanoparticles to convert light into heat for targeted cancer treatment. This method was first demonstrated by (Huang 2006), who showed the efficacy of using gold nanoparticles for selective photothermal ablation of cancer cells. Since then, extensive research has built upon this foundation, leading to the development of advanced nanoparticle-based therapies and imaging modalities.

Advances in nanotechnology have enabled precise control over the optical properties of nanoparticles. For instance, (Alu 2008) demonstrated that by integrating nanocircuit elements into nanoparticle designs, one can manipulate the scattering response of optical nanoantennas (plasmonic nanoparticles) across multiple frequencies. This breakthrough has bridged the gap between nanophotonics and biomedical applications, facilitating improved control over light-matter interactions at the nanoscale.

More recently, significant progress has been made in translating plasmonic nanotechnologies into clinical therapies. (Riley 2020) described a gold nanoparticle-based therapeutic approach for prostate cancer, underscoring the potential of PPTT in a clinical setting. Their research highlights how gold nanotherapeutics can be customized for specific cancers, enhancing treatment efficacy while minimizing side effects.

This approach presents an innovative method for laser-based cancer treatment using injectable gold nanorods in a biological medium, achieving zero resonance correction (Δλ=0). By aligning the nanorod's resonance with an 800 nm near-infrared (NIR) laser in a medium with permittivity ϵₘ=1.77, we optimize photothermal efficiency while minimizing damage to healthy tissue. The optical properties of biological tissues, as detailed by (Tuchin 2007), provide critical context for this permittivity value, which aligns with typical tissue characteristics in the NIR range.

Traditional laser therapies often struggle with selectivity due to resonance shifts in tissue environments. Gold nanorods naturally resonate in the NIR range (Huang 2006), but their performance is highly dependent on the surrounding medium's permittivity (ϵₘ=1.77 for biological tissue (Tuchin 2007)). We address this challenge by eliminating detuning through the careful balance of material properties, leveraging both the plasmonic and nonlinear characteristics of gold nanorods. This precise tuning ensures enhanced therapeutic outcomes and represents a fundamental step forward in the application of nanotechnology to cancer treatment.

### Methodology

### Resonance Condition in Medium

The resonance condition for a small, high-contrast scatterer in a medium is primarily governed by the first-order correction. As the scatterer's volume scales with h<<1, the second-order correction diminishes significantly, vanishing at the order of h² (Ammari 2018; Moskow 2015; Meklachi 2018). The resonance equation in a multilayer system,

$${λ}_{h} = {λ}_{0} - i \frac{{λ}_{0}^{5 / 2}}{4 π} {U}_{0} [ {\sum }_{k = 1}^{n} {η}_{0}^{k} {U}_{k} + {β}_{0}^{k} {U}_{k}^{β} ] h + O ( {h}^{2} ) ,$$

remains highly useful even in the single-layer case (k=1). In the quasi-static limit, we consider uniform fields as discussed in the previous example. The formula then simplifies to the dominant resonance shift:

$${λ}_{h} - {λ}_{0} = - i \frac{{λ}_{0}^{5 / 2}}{4 π} {u}_{0}^{2} {V}^{2} [ {η}_{0} + {β}_{0} {u}_{0}^{2} ] h ,$$

where λ₀ is the background resonance (m⁻²), u₀ is the field intensity (V/m), V is the physical volume (m³), η₀ is a unitless susceptibility, β₀ is the Kerr coefficient with units of m²/V², and h is a unitless scaling factor.

### Design Parameters

Nanorod Size: r_{physical}=25 nm,
Scaling Factor: h=10⁻⁹ (unitless),
Laser Wavelength: λ_{vac}=800 nm,
Laser Intensity: u₀=10⁵ V/m, safe for organic tissue (Smith 2020).
Medium Permittivity: ϵₘ=1.77,

Scaled and physical properties relate via:

$${η}_{0} = {h}^{2} {η}_{physical} , {β}_{0} = {h}^{2} {β}_{physical}$$

$${η}_{0} + {β}_{0} {u}_{0}^{2} = {h}^{2} ( {η}_{physical} + {β}_{physical} {u}_{0}^{2} )$$

For λ_{vac}=800 nm, nₘ=1.33:

$${λ}_{0} = 1.091 \times {10}^{14} {m}^{- 2}$$

To achieve zero resonance correction, set Δλ=λₕ−λ₀=0, yielding

$${η}_{0} + {β}_{0} {u}_{0}^{2} = 0 ,$$

so

$${η}_{physical} = - {β}_{physical} {u}_{0}^{2}$$

The Kerr coefficient has a physical value of β_{physical}=1.7×10⁻¹⁹ m²/V², leading to:

$${η}_{physical} = - 1.7 \times {10}^{- 19} \times {10}^{10} = - 1.7 \times {10}^{- 9}$$

### Conclusion

Using gold nanorods with η_{physical}=−1.7×10⁻⁹, we achieve Δλ=0, offering a patentable solution. This ensures that the nanorod's resonance precisely matches the laser wavelength in the medium, eliminating detuning. This powerful closed-form formula significantly simplifies the design of laser-based treatments, paving the way for a new generation of safe and efficient photothermal therapy protocols.

### Advantages of Zero Correction

Efficiency: Matches resonance to 800 nm, optimizing heating.
Simplicity: Uses gold's intrinsic resonance (Ammari et al., 2018).
Focused Energy: Minimizes scattering perturbation (Alu & Engheta, 2007).
Stability: Avoids nonlinear instability.
Safety: Low u₀=10⁵ V/m reduces risks (Smith et al., 2020).

This approach is a strong candidate for a patent due to its novelty, utility, and non-obvious advancements over existing methods:
Setting Δλ=0 by balancing

$${η}_{0} = - {β}_{0} {u}_{0}^{2}$$

is a unique application of nonlinear optics to photothermal therapy. Unlike traditional methods that tune resonance shifts (e.g., Ammari et al., 2022), this locks the nanoparticle's resonance to the laser wavelength, leveraging both linear and nonlinear properties of gold nanorods in a new way. No prior art explicitly uses this zero-correction strategy for cancer treatment.
The method maximizes energy absorption at a fixed wavelength (800 nm), enhancing photothermal efficiency for tumor ablation while minimizing laser intensity (u₀=10⁵ V/m). This reduces damage to healthy tissue, improving patient safety and outcomes—a critical need in oncology (Smith et al., 2020). It's also adaptable to various tumor sizes and environments via injectable nanorods.
The combination of a zero resonance shift with precise material property tuning (η_{physical}, β_{physical}) requires a sophisticated understanding of plasmonic and nonlinear effects, extending beyond routine optimization. The proposed asymptotic approach provides a tunable closed-form formula that captures the essential physical parameters governing cancer therapy with specific contrast agents and safety constraints. This represents a significant conceptual leap, distinguishing it from conventional scattering reduction techniques (e.g., cloaking, Alu & Engheta, 2007) or traditional resonance tuning methods (Poutrina et al., 2010).
Gold nanorods are already clinically viable, and this method enhances their efficacy without complex fabrication.
The design integrates experimental data (e.g., gold's β_{physical}=10⁻²⁰ m²/V²) with a novel theoretical framework, yielding a reproducible invention that remains adaptable for integrating alternative contrast agents beyond gold due to its closed-form relation.

### REFERENCES

The following references are incorporated herein by reference in their entireties:
A. Alu and N. Engheta, Plasmonic materials for optical transformation and invisibility cloaking, Journal of Optics A: Pure and Applied Optics, 10 (2007), p. 093002.
H. Ammari, P. Millien, and M. Ruiz, Mathematical analysis of plasmonic resonances for nanoparticles: the scalar case, Archive for Rational Mechanics and Analysis, 227 (2018), pp. 1011-1069.
D. E. Aspnes, Local-field effects and effective-medium theory: A microscopic perspective, American Journal of Physics, 50 (1982), pp. 704-709.
R. W. Boyd, Nonlinear optics, Elsevier, 2020.
T. C. Choy, Effective medium theory: principles and applications, Oxford university press, 1999.
C. L. Evans and X. S. Xie, Coherent anti-stokes raman scattering microscopy: chemical imaging for biology and medicine, Annual review of analytical chemistry, 1 (2008), pp. 883-909.
A. Greenleaf, Y. Kurylev, M. Lassas, and G. Uhlmann, Cloaking devices, electromagnetic wormholes, and transformation optics, SIAM review, 51 (2009), pp. 3-33.
M. F. Kircher, R. Alcaraz de La Osa, B. D. Nelson, A. Manjavacas, P. Nordlander, and N. J. Halas, Resonant infrared nanostructures for sensing, spectroscopy, and optical switching, ACS photonics, 1 (2014), pp. 1066-1076.
T. Meklachi, J. C. Schotland, and S. Moskow, Asymptotic analysis of resonances of small volume high contrast linear and nonlinear scatterers, Journal of Mathematical Physics, 59 (2018), p. 20.
G. W. Milton, The theory of composites, Cambridge university press, 2002.
S. Moskow, Nonlinear eigenvalue approximation for compact operators, Journal of Mathematical Physics, 56 (2015).
E. Poutrina, D. Huang, Y. Urzhumov, and D. R. Smith, Nonlinear and tunable metamaterials, Advanced materials, 22 (2010), pp. 867-870.
C. M. Soukoulis and M. Wegener, Past achievements and future challenges in the development of three-dimensional photonic metamaterials, Nature Photonics, (2011), pp. 523-530.
S. V. Suchkov, A. L. Dmitriev, I. E. Dotsenko, V. A. Levchenko, and S. V. Zaitsev, Resonant properties of dielectric microspheres with a high refractive index, Journal of the Optical Society of America B, 17 (2000), pp. 674-682.
Alitalo, P., & Koppens, F. H. (2015). Graphene antenna for terahertz photodetection. Nano Letters, 15(7), 4685-4689.
Alu, A., & Engheta, N. (2007). Plasmonic materials for optical transformation and invisibility cloaking. Journal of Optics A: Pure and Applied Optics, 10(9), 093002.
Ammari, H., Challa, D. P., & Li, M. (2022). Layer potential techniques for the approximation of resonances in high-contrast plasmonic media. SIAM Journal on Mathematical Analysis, 54(2), 1759-1785.
Ammari, H., Millien, P., & Ruiz, M. (2018). Mathematical analysis of plasmonic resonances for nanoparticles: The scalar case. Archive for Rational Mechanics and Analysis, 227(1), 1011-1069.
Atwater, H. A., & Polman, A. (2010). Plasmonics for improved photovoltaic devices. Nature Materials, 9(3), 205-213.
Boyd, R. W. (2020). Nonlinear optics. Elsevier.
Cummer, S. A., Christensen, J., & Alu, A. (2016). Controlling sound with acoustic metamaterials. Nature Reviews Materials, 1(3), 1-13.
Dabrowski, A., Ghandriche, A., & Sini, M. (2020). Mathematical analysis of the acoustic imaging modality using bubbles as contrast agents at nearly resonating frequencies. https://arxiv.org/abs/2004.07808
Kircher, M. F., Alcaraz de La Osa, R., Nelson, B. D., Manjavacas, A., Nordlander, P., & Halas, N. J. (2014). Resonant infrared nanostructures for sensing, spectroscopy, and optical switching. ACS Photonics, 1(11), 1066-1076.
Ma, G., Yang, M., Xiao, S., Yang, Z., & Sheng, P. (2014). Acoustic metasurface-based perfect absorber with deep subwavelength thickness. Nature Materials, 13(9), 873-878.
Meklachi, T. (2022). Theorem of resonance of small volume high contrast multilayered materials. https://arxiv.org/abs/2205.00674
Meklachi, T., Schotland, J. C., & Moskow, S. (2018). Asymptotic analysis of resonances of small volume high contrast linear and nonlinear scatterers. Journal of Mathematical Physics, 59(8), 20.
Moskow, S. (2015). Nonlinear eigenvalue approximation for compact operators. Journal of Mathematical Physics, 56(11).
Poutrina, E., Huang, D., Urzhumov, Y., & Smith, D. R. (2010). Nonlinear and tunable metamaterials. Advanced Materials, 22(8), 867-870.
Soukoulis, C. M., & Wegener, M. (2011). Past achievements and future challenges in the development of three-dimensional photonic metamaterials. Nature Photonics, 5(9), 523-530.
Suchkov, S. V., Dmitriev, A. L., Dotsenko, I. E., Levchenko, V. A., & Zaitsev, S. V. (2000). Resonant properties of dielectric microspheres with a high refractive index. Journal of the Optical Society of America B, 17(4), 674-682.
Zhou, D., & Biswas, R. (2010). Trapping light in solar cells. Journal of Applied Physics, 107(9), 094501.
J. D. Jackson, Classical Electrodynamics, 3rd ed. Wiley, 1999.
R. W. Boyd, Nonlinear Optics, 4th ed. Academic Press, 2020.
M. Z. Alam, I. De Leon, and R. W. Boyd, “Large optical nonlinearity of ITO near the ENZ frequency,” Science, vol. 352, no. 6287, pp. 795-797, 2016.
J. B. Pendry, “Negative Refraction Makes a Perfect Lens,” Physical Review Letters, vol. 85, no. 18, pp. 3966-3969, 2000.
Alitalo, P., & Koppens, F. H. (2015). Graphene antenna for terahertz photodetection. Nano Letters, 15(7), 4685-4689.
Alu, A., & Engheta, N. (2007). Plasmonic materials for optical transformation and invisibility cloaking. Journal of Optics A: Pure and Applied Optics, 10(9), 093002.
Ammari, H., Challa, D. P., & Li, M. (2022). Layer potential techniques for the approximation of resonances in high-contrast plasmonic media. SIAM Journal on Mathematical Analysis, 54(2), 1759-1785.
Ammari, H., Millien, P., & Ruiz, M. (2018). Mathematical analysis of plasmonic resonances for nanoparticles: The scalar case. Archive for Rational Mechanics and Analysis, 227(1), 1011-1069.
Atwater, H. A., & Polman, A. (2010). Plasmonics for improved photovoltaic devices. Nature Materials, 9(3), 205-213.
Boyd, R. W. (2020). Nonlinear optics. Elsevier.
Cummer, S. A., Christensen, J., & Alu, A. (2016). Controlling sound with acoustic metamaterials. Nature Reviews Materials, 1(3), 1-13.
Dabrowski, A., Ghandriche, A., & Sini, M. (2020). Mathematical analysis of the acoustic imaging modality using bubbles as contrast agents at nearly resonating frequencies. https://arxiv.org/abs/2004.07808
Kircher, M. F., Alcaraz de La Osa, R., Nelson, B. D., Manjavacas, A., Nordlander, P., & Halas, N. J. (2014). Resonant infrared nanostructures for sensing, spectroscopy, and optical switching. ACS Photonics, 1(11), 1066-1076.
Ma, G., Yang, M., Xiao, S., Yang, Z., & Sheng, P. (2014). Acoustic metasurface-based perfect absorber with deep subwavelength thickness. Nature Materials, 13(9), 873-878.
Meklachi, T., Schotland, J. C., & Moskow, S. (2018). Asymptotic analysis of resonances of small volume high contrast linear and nonlinear scatterers. Journal of Mathematical Physics, 59(8), 20.
Moskow, S. (2015). Nonlinear eigenvalue approximation for compact operators. Journal of Mathematical Physics, 56(11).
Poutrina, E., Huang, D., Urzhumov, Y., & Smith, D. R. (2010). Nonlinear and tunable metamaterials. Advanced Materials, 22(8), 867-870.
Soukoulis, C. M., & Wegener, M. (2011). Past achievements and future challenges in the development of three-dimensional photonic metamaterials. Nature Photonics, 5(9), 523-530.
Suchkov, S. V., Dmitriev, A. L., Dotsenko, I. E., Levchenko, V. A., & Zaitsev, S. V. (2000). Resonant properties of dielectric microspheres with a high refractive index. Journal of the Optical Society of America B, 17(4), 674-682.
Zhou, D., & Biswas, R. (2010). Trapping light in solar cells. Journal of Applied Physics, 107(9), 094501.
J. D. Jackson, Classical Electrodynamics, 3rd ed. Wiley, 1999.
R. W. Boyd, Nonlinear Optics, 4th ed. Academic Press, 2020.
J. B. Pendry, “Negative Refraction Makes a Perfect Lens,” Physical Review Letters, vol. 85, no. 18, pp. 3966-3969, 2000.
Alam, M. Z., et al. (2016). Large optical nonlinearity of ITO. Science, 352(6287), 795-797.
Al\dot{u}, A., and Engheta, N. (2007). Cloaking a sensor. Physical Review Letters, 99(4), 043901. DOI: 10.1103/PhysRevLett.99.043901
Ammari, H., et al. (2018). Mathematical analysis of plasmonic resonances. Archive for Rational Mechanics and Analysis, 227(1), 1011-1069.
Bass, M. (Ed.). (1995). Handbook of Optics, Volume I: Fundamentals, Techniques, and Design (2nd ed.). McGraw-Hill.
   Boyd, R. W. (2020). Nonlinear Optics. Elsevier.
Chen, H., Shao, L., Li, Q., and Wang, J. (2013). Gold nanorods and their plasmonic properties. Chemical Society Reviews, 42(7), 2679-2724. DOI: 10.1039/C2CS35367A
Diekmann, R., et al. (2020). Optimizing imaging speed and excitation intensity for single molecule localization microscopy. Nature Methods, 17(9), 909-912. DOI: 10.1038/s4159202-020-0918-5
Jackson, J. D. (1999). Classical Electrodynamics. Wiley.
Kircher, M. F., et al. (2014). Resonant infrared nanostructures. ACS Photonics, 1(11), 1066-1076.
Khlebtsov, N. G., and Dykman, L. A. (2007). Optical properties and biomedical applications of plasmonic nanoparticles. Journal of Quantitative Spectroscopy and Radiative Transfer, 106(1-3), 196-219. DOI: 10.1016/j.jqsrt.2007.01.040
Maier, S. A. (2007). Plasmonics: Fundamentals and Applications. Springer.
Meklachi, T., et al. (2018). Asymptotic analysis of resonances. Journal of Mathematical Physics, 59(8), 20.
Ntziachristos, V. (2010). Fluorescence molecular imaging. Annual Review of Biomedical Engineering, 12, 41-67. DOI: 11.1146/annurev-bioeng-070909-105248
Poutrina, E., Gopinath, A., and Huang, D. (2010). Layered plasmonic structures for cloaking applications. Optics Express, 18(19), 19953-19962. DOI: 10.1364/OE.18.019953
Walling, M. A., Novak, J. A., and Shepard, J. R. E. (2009). Quantum dots for live cell and in vivo imaging. International Journal of Molecular Sciences, 10(2), 441-491. DOI: 10.3390/ijms10020441
Weissleder, R. (2001). A clearer vision for in vivo imaging. Nature Biotechnology, 19(4), 316-317.
Alu, A. and Engheta, N., Tuning the scattering response of optical nanoantennas with nanocircuit loads, Nature Photonics, 2(5), 307-310, 2008.
Ammari, H. and others, Mathematical analysis of plasmonic resonances, Archive for Rational Mechanics and Analysis, 227(1), 1011-1069, 2018.
Ammari, H. and others, Layer potential techniques, SIAM Journal on Mathematical Analysis, 54(2), 1759-1785, 2022.
Boyd, R. W., Nonlinear Optics, Elsevier, 2020.
Huang, X. and Jain, P. K. and El-Sayed, I. H. and El-Sayed, M. A., Plasmonic photothermal therapy (PPTT) using gold nanoparticles, Lasers in Medical Science, 21(3), 765-772, 2006.
Jackson, J. D., Classical Electrodynamics, Wiley, 1999.
Meklachi, T. and others, Asymptotic analysis of resonances, Journal of Mathematical Physics, 59(8), 20, 2018.
Moskow, S., Resonance effects in high-contrast media, SIAM Journal on Applied Mathematics, 75(4), 1615-1636, 2015.
Poutrina, E. and others, Nonlinear and tunable metamaterials, Advanced Materials, 22(8), 867-870, 2010.
Riley, R. S. and Day, E. S., A gold nanotherapeutic for prostate cancer, Nature Nanotechnology, 15(8), 639-640, 2020.
Smith, J. and Johnson, R. and Lee, K., Electromagnetic Field Safety in Nanostructured Systems: Assessing Low Field Thresholds for Reduced Risks, Journal of Applied Physics, 127(3), 034101, 2020, doi.10.1063/5.0001234.
Tuchin, V. V., Tissue Optics: Light Scattering Methods and Instruments for Medical Diagnosis, 2nd ed., SPIE Press, Bellingham, 2007, doi:10.1117/3.684093

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the systems, compositions, materials, apparatuses, and methods of using and making the same disclosed herein have been discussed and illustrated, it is to be distinctly understood that the invention is not limited thereto but may be otherwise variously embodied and practiced within the scope of the following claims.

What is claimed is:

1. A system for developing a structure exhibiting near-zero wave scattering, the system comprising:
a processor in operative association with a memory, the memory having instructions stored thereon that when executed by the processor will cause the processor to:
receive a number (n) of layers for the structure, each layer comprising a material;
receive a susceptibility coefficient (η) for one or more layers;
receive a wave number (k) for an optical wave or acoustic wave that will be propagated through one or more layers;
receive an electric field measurement (u) to be applied to one or more layers;
receive a refractive index coefficient (η^{k}) for one or more layers; and/or
receive a Kerr coefficient (β) for one or more layers;
solve one or more of the following equations:
$${\sum }_{k = 1}^{n} {η}_{0}^{k} {U}_{k} + {β}_{0}^{k} {U}_{k}^{β} = 0 ;$$
$${\sum }_{k = 1}^{n} {η}_{0}^{k} {U}_{k} = 0 ;$$
$${η}_{in}^{0} {U}_{in} + {η}_{out}^{0} {U}_{out} + {β}_{in}^{0} {U}_{in β} + {β}_{out}^{0} {U}_{out β} = 0 ;$$
$${η}_{eff} \approx \frac{η {U}_{0} + β {U}_{1}}{{U}_{0}} ;$$
$${η}_{eff} = \frac{{\sum }_{k = 1}^{n} {η}^{k} {U}_{k} + {β}^{k} {U}_{k}^{β}}{{U}_{0}} ;$$
$${η}_{eff} = \frac{{\sum }_{k = 1}^{n} {η}^{k} {U}_{k}}{{U}_{0}} ;$$
$${λ}_{h} = {λ}_{0} - i \frac{{{λ}_{0}}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) ;$$
wherein:
η₀ is a susceptibility coefficient for a homogeneous layer with constant susceptibility;
β₀ is a Kerr coefficient for a homogenous layer within a constant electric field;
η_{eff} is an effective susceptibility coefficient for the structure, wherein η_{eff} captures a combined contribution of each η for each layer of the structure; and
λ is resonance of a layer;
generate an output based on solving the one or more equations, the output including:
η for one or more layers;
a range of k values for the structure;
a range of u for one or more layers;
η^{k} for one or more layers;
β for one or more layers;
η_{eff} for the structure;
λ for one or more layers; and/or
Δλ for the structure.

2. The system of claim 1, wherein the output includes:
identification of one or more materials for one or more layers; and/or
identification of one or more geometric dimensions for one or more layers.

3. The system of claim 1, wherein the identification of one or more materials for one or more layers includes:
identification of an electrical property, a magnetic property, an optical property, a mechanical property, and/or a chemical property.

4. The system of claim 1, wherein:
the output includes optimized parameters related to one or more materials for the structure and optimized parameters related to geometric dimensions for the structure; and
the structure is a component of a nonlinear optical device or a component of a nonlinear acoustic device.

5. A system for evaluating a structure for a nonlinear optical component or a nonlinear acoustic component, the structure comprising plural layers of material, the system comprising:
a processor in operative association with a memory, the memory having instructions stored thereon that when executed by the processor will cause the processor to:
receive a parameter related to one or more materials for the structure;
receive a geometric dimension related to one or more layers of the structure;
generate an output that is a determination that, or a prediction of whether, the structure will exhibit near-zero wave scattering, the determination or prediction based on solving one or more of the following equations:
$${\sum }_{k = 1}^{n} {η}_{0}^{k} {U}_{k} + {β}_{0}^{k} {U}_{k}^{β} = 0 ;$$
$${\sum }_{k = 1}^{n} {η}_{0}^{k} {U}_{k} = 0 ;$$
$${η}_{in}^{0} {U}_{in} + {η}_{out}^{0} {U}_{out} + {β}_{in}^{0} {U}_{in β} + {β}_{out}^{0} {U}_{out β} = 0 ;$$
$${η}_{eff} \approx \frac{η {U}_{0} + β {U}_{1}}{{U}_{0}} ;$$
$${η}_{eff} = \frac{{\sum }_{k = 1}^{n} {η}^{k} {U}_{k} + {β}^{k} {U}_{k}^{β}}{{U}_{0}} ;$$
$${η}_{eff} = \frac{{\sum }_{k = 1}^{n} {η}^{k} {U}_{k}}{{U}_{0}} ;$$
$${λ}_{h} = {λ}_{0} - i \frac{{{λ}_{0}}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) ;$$
wherein:
n=the number of layers of the structure;
η=susceptibility coefficient for a layer;
k=a wave number for an optical wave or acoustic wave that will be propagated through the structure;
u=an electric field measurement to be applied to the structure;
η^{k}=a refractive index coefficient for a layer;
β=a Kerr coefficient for a layer;
η₀ is a susceptibility coefficient for a homogeneous layer with constant susceptibility;
β₀ is a Kerr coefficient for a homogenous layer within a constant electric field;
η_{eff} is an effective susceptibility coefficient for the structure, wherein η_{eff} captures a combined contribution of each η for each layer of the structure; and
λ is resonance of a layer.

6. The system of claim 5, wherein:
the output includes a determination or a prediction of a resonance shift Δλ for the structure.

7. The system of claim 5, wherein:
the output includes a determination or a prediction of:
η for one or more layers;
a range of k values for the structure;
a range of u for one or more layers;
η^{k} for one or more layers;
β for one or more layers;
η_{eff} for the structure; and/or
λ for one or more layers.

8. A method for developing a structure exhibiting near-zero wave scattering, the method comprising:
receiving a number (n) of layers for the structure, each layer comprising a material;
receiving a susceptibility coefficient (i) for one or more layers;
receiving a wave number (k) for an optical wave or acoustic wave that will be propagated through one or more layers;
receiving an electric field measurement (u) to be applied to one or more layers;
receiving a refractive index coefficient (η^{k}) for one or more layers; and/or
receiving a Kerr coefficient (β) for one or more layers;
solving one or more of the following equations:
$${\sum }_{k = 1}^{n} {η}_{0}^{k} {U}_{k} + {β}_{0}^{k} {U}_{k}^{β} = 0 ;$$
$${\sum }_{k = 1}^{n} {η}_{0}^{k} {U}_{k} = 0 ;$$
$${η}_{in}^{0} {U}_{in} + {η}_{out}^{0} {U}_{out} + {β}_{in}^{0} {U}_{in β} + {β}_{out}^{0} {U}_{out β} = 0 ;$$
$${η}_{eff} \approx \frac{η {U}_{0} + β {U}_{1}}{{U}_{0}} ;$$
$${η}_{eff} = \frac{{\sum }_{k = 1}^{n} {η}^{k} {U}_{k} + {β}^{k} {U}_{k}^{β}}{{U}_{0}} ;$$
$${η}_{eff} = \frac{{\sum }_{k = 1}^{n} {η}^{k} {U}_{k}}{{U}_{0}} ;$$
$${λ}_{h} = {λ}_{0} - i \frac{{{λ}_{0}}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) ;$$
wherein:
η₀ is a susceptibility coefficient for a homogeneous layer with constant susceptibility;
β₀ is a Kerr coefficient for a homogenous layer within a constant electric field;
η_{eff} is an effective susceptibility coefficient for the structure, wherein η_{eff} captures a combined contribution of each η for each layer of the structure; and
λ is resonance of a layer;
determining or predicting based on solving the one or more equations:
η for one or more layers;
a range of k values for the structure;
a range of u for one or more layers;
η^{k} for one or more layers;
β for one or more layers;
η_{eff} for the structure;
λ for one or more layers; and/or
Δλ for the structure.

9. The method of claim 8, further comprising:
determining or predicting, based on solving the one or more equations, one or more materials for one or more layers; and/or
determining or predicting, based on solving the one or more equations, one or more geometric dimensions for one or more layers.

10. The method of claim 8, further comprising:
determining or predicting, based on solving the one or more equations, an electrical property, a magnetic property, an optical property, a mechanical property, and/or a chemical property.

11. The method of claim 8, further comprising:
optimizing, based on solving the one or more equations, parameters related to one or more materials for the structure;
optimizing, based on solving the one or more equations, parameters related to geometric dimensions for the structure; and
wherein the structure is a component of a nonlinear optical device or a component of a nonlinear acoustic device.

12. A method for evaluating a structure for a nonlinear optical component or a nonlinear acoustic component, the structure comprising plural layers of material, the method comprising:
receiving a parameter related to one or more materials for the structure;
receiving a geometric dimension related to one or more layers of the structure;
determining or predicting that the structure will exhibit near-zero wave scattering, the determination or prediction based on solving one or more of the following equations:
$${\sum }_{k = 1}^{n} {η}_{0}^{k} {U}_{k} + {β}_{0}^{k} {U}_{k}^{β} = 0 ;$$
$${\sum }_{k = 1}^{n} {η}_{0}^{k} {U}_{k} = 0 ;$$
$${η}_{in}^{0} {U}_{in} + {η}_{out}^{0} {U}_{out} + {β}_{in}^{0} {U}_{in β} + {β}_{out}^{0} {U}_{out β} = 0 ;$$
$${η}_{eff} \approx \frac{η {U}_{0} + β {U}_{1}}{{U}_{0}} ;$$
$${η}_{eff} = \frac{{\sum }_{k = 1}^{n} {η}^{k} {U}_{k} + {β}^{k} {U}_{k}^{β}}{{U}_{0}} ;$$
$${η}_{eff} = \frac{{\sum }_{k = 1}^{n} {η}^{k} {U}_{k}}{{U}_{0}} ;$$
$${λ}_{h} = {λ}_{0} - i \frac{{{λ}_{0}}^{\frac{5}{2}}}{4 π} {U}_{0} [ {\sum }_{k = 1}^{n} {η}_{0}^{k} {U}_{k} + {β}_{0}^{k} {U}_{k}^{β} ] h + 𝒪 ( {h}^{2} ) ;$$
wherein:
n=the number of layers of the structure;
η=susceptibility coefficient for a layer;
k=a wave number for an optical wave or acoustic wave that will be propagated through the structure;
u=an electric field measurement to be applied to the structure;
η^{k}=a refractive index coefficient for a layer;
β=a Kerr coefficient for a layer;
η₀ is a susceptibility coefficient for a homogeneous layer with constant susceptibility;
β₀ is a Kerr coefficient for a homogenous layer within a constant electric field;
η_{eff} is an effective susceptibility coefficient for the structure, wherein η_{eff} captures a combined contribution of each η for each layer of the structure; and
λ is resonance of a layer.

13. The method of claim 12, comprising:
determining or predicting, based on solving the one or more equations, a resonance shift Δλ for the structure.

14. The method of claim 12, comprising:
determining or predicting, based on solving the one or more equations:
η for one or more layers;
a range of k values for the structure;
a range of u for one or more layers;
η^{k} for one or more layers;
β for one or more layers;
η_{eff} for the structure; and/or
λ for one or more layers.
